(19) United States
(12) Patent Application Publication
(10) Pub. No.: US 2023/0369230 A1
(43) Pub. Date: Nov. 16, 2023

(54) PACKAGE COMPRISING AN INTERCONNECTION DIE LOCATED BETWEEN METALLIZATION PORTIONS

(71) Applicant: QUALCOMM Incorporated, San Diego, CA (US)

(72) Inventors: Yangyang SUN, San Diego, CA (US); Manuel ALDRETE, Encinitas, CA (US); Lily ZHAO, San Diego, CA (US)

(21) Appl. No.: 17/742,001

(22) Filed: May 11, 2022

(51) Int. Cl. H01L 23/538; H01L 23/00; H01L 23/31; H01L 25/10; H01L 25/00; H01L 21/56

(52) U.S. Cl. CPC H01L 23/5383; H01L 24/08; H01L 23/3107; H01L 23/5384; H01L 25/105; H01L 25/50; H01L 21/56

(57) ABSTRACT

A package comprising a first metallization portion, a first integrated device, an interconnection die, a second metallization portion, and an encapsulation layer. The first metallization portion includes at least one first dielectric layer and a first plurality of metallization interconnects. The first integrated device is coupled to the first metallization portion. The interconnection die is coupled to the first metallization portion. The second metallization portion coupled to the first metallization portion through the interconnection die such that the first integrated device and the interconnection die are located between the first metallization portion and the second metallization portion. The second metallization portion includes at least one second dielectric layer and a second plurality of metallization interconnects. The encapsulation layer coupled to the first metallization portion and the second metallization portion, wherein the encapsulation layer is located between the first metallization portion and the second metallization portion.

### FIELD

Various features relate to packages with metallization portions and integrated devices.

### BACKGROUND

A package may include a substrate and integrated devices. These components are coupled together to provide a package that may perform various electrical functions. There is an ongoing need to provide better performing packages and reduce the overall size of the packages.

### SUMMARY

Various features relate to packages with metallization portions and integrated devices.

One example provides a package comprising a first metallization portion, a first integrated device, an interconnection die, a second metallization portion, and an encapsulation layer. The first metallization portion includes at least one first dielectric layer and a first plurality of metallization interconnects. The first integrated device is coupled to the first metallization portion. The interconnection die is coupled to the first metallization portion. The second metallization portion coupled to the first metallization portion through the interconnection die such that the first integrated device and the interconnection die are located between the first metallization portion and the second metallization portion. The second metallization portion includes at least one second dielectric layer and a second plurality of metallization interconnects. The encapsulation layer coupled to the first metallization portion and the second metallization portion, wherein the encapsulation layer is located between the first metallization portion and the second metallization portion.

Another example provides a device that includes a first package. The first package includes a first metallization portion, a first integrated device, a means for die interconnection, a second metallization portion, and an encapsulation layer. The first metallization portion includes at least one first dielectric layer and a first plurality of metallization interconnects. The first integrated device is coupled to the first metallization portion. The means for die interconnection is coupled to the first metallization portion. The second metallization portion coupled to the first metallization portion through the means for die interconnection such that the first integrated device and the means for die interconnection are located between the first metallization portion and the second metallization portion. The second metallization portion includes at least one second dielectric layer and a second plurality of metallization interconnects. The encapsulation layer coupled to the first metallization portion and the second metallization portion, wherein the encapsulation layer is located between the first metallization portion and the second metallization portion

Another example provides a method for fabricating a package. The method provides a first metallization portion. The method couples a first integrated device to the first metallization portion. The method couples an interconnection die to the first metallization portion. The method forms an encapsulation layer over the first metallization portion, the first integrated device and the interconnection die. The method forms a second metallization portion over the encapsulation layer such that the second metallization portion is coupled to the first metallization portion through the interconnection die.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a metallization portion and at least one interconnection die.

FIG. 2 illustrates an exemplary cross sectional profile view of a package that includes a metallization portion and at least one interconnection die.

FIG. 3 illustrates an exemplary cross sectional profile view of a package that includes at least one interconnection die.

FIG. 4 illustrates an exemplary cross sectional profile view of a package that includes at least one interconnection die.

FIG. 5 illustrates an exemplary sequence for fabricating an interconnection die.

FIG. 6 illustrates an exemplary sequence for fabricating an interconnection die.

FIGS. 7A-7B illustrate an exemplary sequence for fabricating an interconnection die.

FIGS. 8A-8B illustrate an exemplary sequence for fabricating an interconnection die.

FIG. 9 illustrates an exemplary flow chart of a method for fabricating an interconnection die.

FIG. 10A-10B illustrate an exemplary sequence for fabricating a package that includes a metallization portion and an interconnection die.

FIG. 11 illustrates an exemplary flow chart of a method for fabricating a package that includes a metallization portion and an interconnection die.

FIGS. 12A-12B illustrate an exemplary sequence for fabricating a metallization portion.

FIG. 13 illustrates an exemplary flow chart of a method for fabricating a metallization portion.

FIG. 14 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a first metallization portion, a first integrated device, an interconnection die, a second metallization portion, and an encapsulation layer. The first metallization portion includes at least one first dielectric layer and a first plurality of metallization interconnects. The first integrated device is coupled to the first metallization portion. The interconnection die is coupled to the first metallization portion. The second metallization portion coupled to the first metallization portion through the interconnection die such that the first integrated device and the interconnection die are located between the first metallization portion and the second metallization portion. The second metallization portion includes at least one second dielectric layer and a second plurality of metallization interconnects. The encapsulation layer coupled to the first metallization portion and the second metallization portion, wherein the encapsulation layer is located between the first metallization portion and the second metallization portion. The first metallization portion may include a first redistribution portion comprising a first plurality of redistribution interconnects. The second metallization portion may include a second redistribution portion comprising a second plurality of redistribution interconnects. A second integrated device may be coupled to the first side of the second metallization portion. A second package may be coupled to the first side of the second metallization portion. The second package may include a substrate, a second integrated device coupled to the substrate, and a second encapsulation layer coupled to the substrate and the second integrated device. As will be further described below, the package provides interconnects with high aspect ratios and high density interconnection, which helps provide improved package performance, while keeping the package small and thin.

### Exemplary Packages Comprising an Interconnection Die

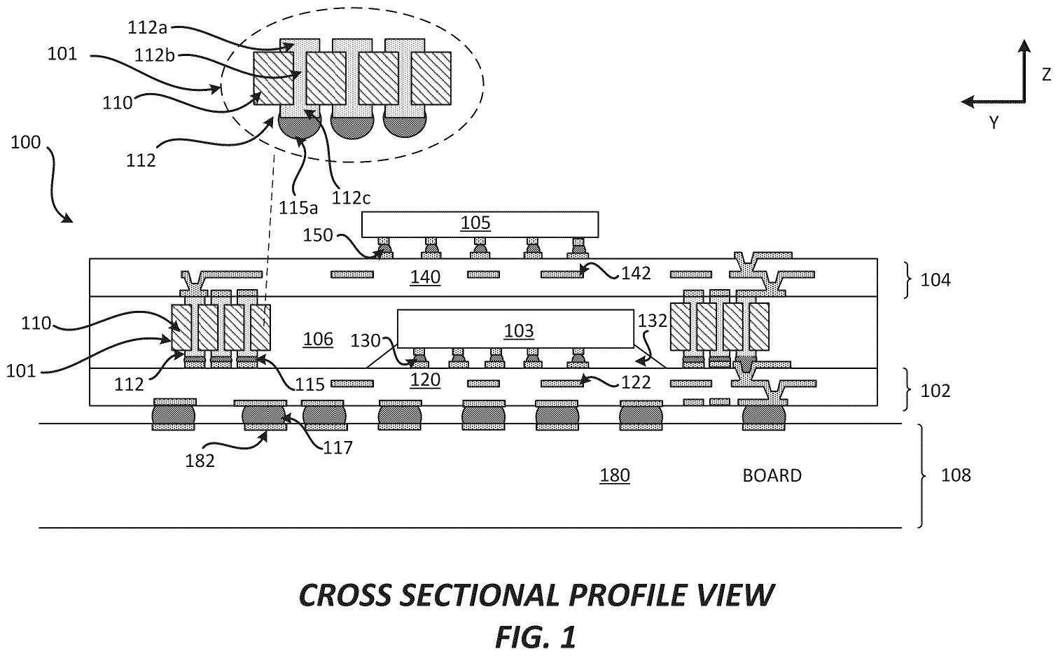

FIG. 1 illustrates a cross sectional profile view of a package 100 that includes a metallization portion and a high density interconnection. The package 100 may include a package on package (PoP). The package 100 is coupled to a board 108 through a plurality of solder interconnects 117. The board 108 includes at least one board dielectric layer 180 and a plurality of board interconnects 182. The board 108 may include a printed circuit board (PCB). The package 100 is coupled to the plurality of board interconnects 182 of the board 108 through the plurality of solder interconnects 117.

The package 100 includes at least one interconnection die 101, a metallization portion 102, a metallization portion 104, an integrated device 103, an integrated device 105, and an encapsulation layer 106. The metallization portion 102 includes at least one dielectric layer 120 and a plurality of metallization interconnects 122. The metallization portion 104 includes at least one dielectric layer 140 and a plurality of metallization interconnects 142. The metallization portion 104 (e.g., second metallization portion) is configured to be coupled (e.g., electrically coupled) to the metallization portion 102 (e.g., first metallization portion) through the at least one interconnection die 101.

The metallization portion 102 may include a redistribution portion (e.g., first redistribution portion). The metallization portion 102 may include a first side and a second side. The first side may be a front side, and the second side may be a back side. The plurality of metallization interconnects 122 may include a plurality of redistribution interconnects (e.g., first plurality of redistribution interconnects). The metallization portion 102 may be a front side metallization portion (e.g., front side redistribution portion) of the package 100. The metallization portion 102 may be a means for metallization interconnection (e.g., means for front side metallization interconnection).

The metallization portion 104 may include a redistribution portion (e.g., second redistribution portion). The metallization portion 104 may include a first side and a second side. The first side may be a front side, and the second side may be a back side. The plurality of metallization interconnects 142 may include a plurality of redistribution interconnects (e.g., second plurality of redistribution interconnects). The metallization portion 104 may be a back side metallization portion (e.g., back side redistribution portion) of the package 100. The metallization portion 104 may be a means for metallization interconnection (e.g., means for back side metallization interconnection).

As mentioned above, a metallization portion (e.g., 102, 104) may include a redistribution portion that includes redistribution interconnects (e.g., redistribution layer (RDL) interconnects). A redistribution interconnect may include portions that have a U-shape or V-shape. The terms “U-shape” and” V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

The integrated device 103 (e.g., first integrated device) is coupled to the first side (e.g., front side) of the metallization portion 102 through a plurality of solder interconnects 130. There may or may not be a plurality of pillar interconnects between the integrated device 103 and the plurality of solder interconnects 130. Thus, the integrated device 103 may be coupled to the metallization portion 102 through a plurality of pillar interconnects and a plurality of solder interconnects 130. An underfill 132 may be located between the integrated device 103 and the metallization portion 102. The at least one interconnection die 101 may be coupled to the first side of the metallization portion 102 through a plurality of solder interconnects 115. As will be further described below, the at least one interconnection die 101 may be configured to provide high aspect ratios interconnects and/or high density interconnects for the package 100. The encapsulation layer 106 may be coupled to the first side (e.g., front side) of the metallization portion 102 and the second side (e.g., back side) of the metallization portion 104. The encapsulation layer 106 may encapsulate (e.g., partial or complete) the integrated device 103 and the at least one interconnection die 101. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process. The encapsulation layer 106 is located between the metallization portion 102 and the metallization portion 104. The at least one interconnection die 101 is located between the metallization portion 102 and the metallization portion 104. The integrated device 103 is located between the metallization portion 102 and the metallization portion 104. The integrated device 103 may include a front side and a back side. The front side of the integrated device 103 may face the metallization portion 102. The back side of the integrated device 103 may face the metallization portion 104. The back side of the integrated device 103 may be covered by the encapsulation layer 106. In some implementations, the back side (e.g., back side surface) of the integrated device 103 may be left exposed (e.g., not covered by the encapsulation layer 106). The at least one interconnection die 101 is located laterally to the integrated device 103. The at least one interconnection die 101 may laterally surround the integrated device 103.

The at least one interconnection die 101 includes a die substrate 110 and a plurality of die interconnects 112. The die substrate 110 may include silicon. The plurality of die interconnects 112 include a pad interconnect 112a (e.g., pad), a via interconnect 112b (e.g., via) and a pad interconnect 112c (e.g., pad). The pad interconnect 112a is coupled to the via interconnect 112b. The via interconnect 112b is coupled to the pad interconnect 112c. The pad interconnect 112c is coupled to the solder interconnect 115a. The solder interconnect 115a is part of the plurality of solder interconnects 115.

The plurality of metallization interconnects 142 from the metallization portion 104 may be coupled to the plurality of die interconnects 112 of the at least one interconnection die 101, such that a solder interconnect is not needed between the interconnection die 101 and the metallization portion 104. That is, the plurality of metallization interconnects 142 may be coupled to the plurality of die interconnects 112 without the need or use of a solder interconnect. Thus, a coupling between an interconnect from the plurality of metallization interconnects 142 and an die interconnect (e.g., 112a) from the plurality of die interconnects 112 may be free of a solder interconnect.

The at least one interconnection die 101 may include a dummy die. The at least one interconnection die 101 may be free of active components. The at least one interconnection die 101 may be free of transistors. The at least one interconnection die 101 may be a means for die interconnection.

The aspect ratio (e.g., height to width ratio, height to diameter ratio) of interconnects between the metallization portion 102 and the metallization portion 104 can be very high. For example, in some implementations, the plurality of die interconnects 112 may have an aspect ratio in a range of about 20:1 to 10:1. In one example, the die interconnect 112b may have an aspect ratio in a range of about 20:1 to 10:1. In one another example, the combination of the die interconnect 112a, the die interconnect 112b and/or the die interconnect 112c may have an aspect ratio in a range of about 20:1 to 10:1. The high aspect ratio helps provide high density interconnects when there is an integrated device between the metallization portion 102 and the metallization portion 104. Also, the pitch of interconnects between the metallization portion 102 and the metallization portion 104 may be relatively small. For example, the plurality of die interconnects 112 may have a pitch between neighboring die interconnects in a range of about 80-270 micrometers. These dimensions are possible through the use of the at least one interconnection die 101, which (i) helps provide a package 100 that is thinner while still able to accommodate the integrated device 103 between two metallization portions, and (ii) helps provide interconnects in an encapsulation layer with low pitches (e.g., 80-270 micrometers), and thus helps provide high-density routing (e.g., high-density interconnects) in an encapsulation layer. The pad interconnect 112c may have a diameter and/or a width of about 20-90 micrometers. The pad interconnect 112b may have a height of about 50-500 micrometers. The pad interconnect 112a may have a diameter and/or a width of about 20-90 micrometers. The pad interconnect 112a may have a thickness of about 5-15 micrometers. The encapsulation layer 106 may have a thickness of about 70-500 micrometers. The spacing between the surfaces of the metallization portion 102 and the metallization portion 104 may equal to the thickness of the encapsulation layer 106. It is noted that the above dimensions are exemplary. Different implementations may have interconnects with different dimensions and/or configurations. The above exemplary dimensions and/or values may be applicable to other packages described in the disclosure.

The integrated device 105 (e.g., second integrated device) is coupled to a first side (e.g., front side) of the metallization portion 104 through a plurality of solder interconnects 150. For example, the integrated device 105 may be coupled to the plurality of metallization interconnects 142 of the metallization portion 104 through the plurality of solder interconnects 150. There may or may not be a plurality of pillar interconnects between the integrated device 105 and the plurality of solder interconnects 150. Thus, the integrated device 103 may be coupled to the metallization portion 104 through a plurality of pillar interconnects and a plurality of solder interconnects 150. The integrated device 105 may be configured to be electrically coupled to the integrated device 103 through the plurality of solder interconnect 150, the plurality of metallization interconnects 142, the at least one interconnection die 101 (a plurality of interconnects 112), the plurality of solder interconnects 115, the plurality of metallization interconnects 122 and/or the plurality of solder interconnects 130.

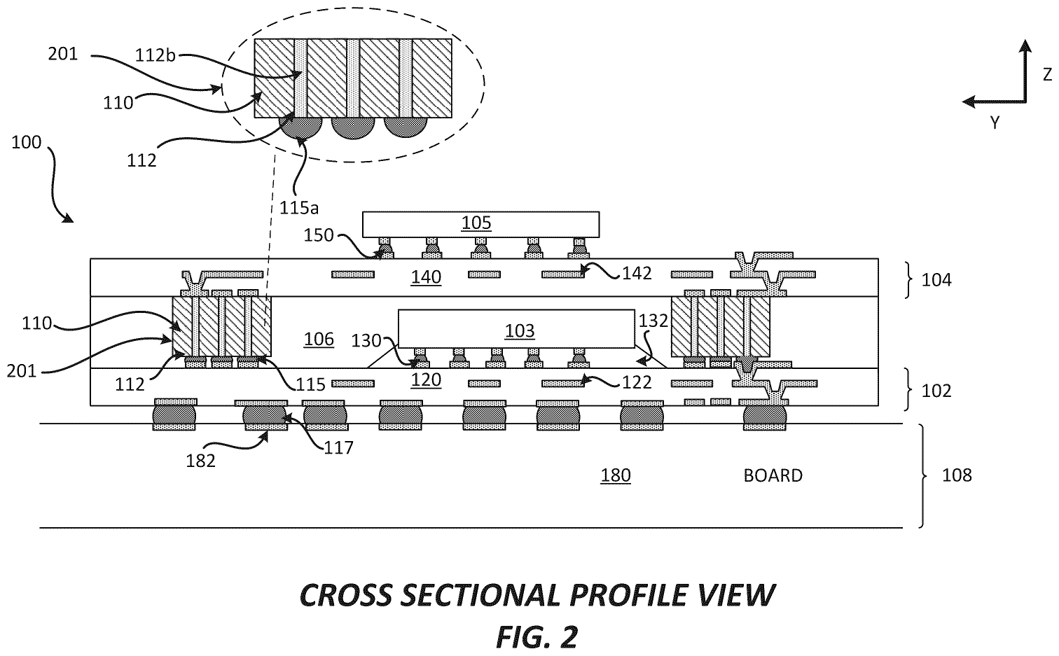

FIG. 2 illustrates a cross sectional profile view of a package 200 that includes a metallization portion and a high density interconnection. The package 200 is similar to the package 100 of FIG. 1, and thus includes the same or similar components as the package 100. The package 200 includes at least one interconnection die 201 that has a different configuration, arrangement and/or design than the at least one interconnection die 101 of FIG. 1.

The package 200 is coupled to the board 108 through the plurality of solder interconnects 117. The board 108 includes at least one board dielectric layer 180 and the plurality of board interconnects 182. The board 108 may include a printed circuit board (PCB).

The package 200 includes at least one interconnection die 201, the metallization portion 102, the metallization portion 104, the integrated device 103, the integrated device 105, and the encapsulation layer 106. The at least one interconnection die 201 is coupled to the first side (e.g., front side) of the metallization portion 102. The metallization portion 104 (e.g., second metallization portion) is configured to be coupled (e.g., electrically coupled) to the metallization portion 102 (e.g., first metallization portion) through the at least one interconnection die 201.

The at least one interconnection die 201 includes the die substrate 110 and the plurality of die interconnects 112. The die substrate 110 may include silicon. The plurality of die interconnects 112 include a via interconnect 112b (e.g., via). In some implementations, the via interconnect 112b of FIG. 2, may have a width and/or diameter of about 100 micrometers. The via interconnect 112b is coupled to the solder interconnect 115a. The solder interconnect 115a is part of the plurality of solder interconnects 115.

The plurality of metallization interconnects 142 from the metallization portion 104 may be coupled to the plurality of die interconnects 112 of the at least one interconnection die 101, such that a solder interconnect is not needed between the interconnection die 101 and the metallization portion 104. That is, the plurality of metallization interconnects 142 may be coupled to the plurality of die interconnects 112 without the need or use of a solder interconnect. Thus, a coupling between an interconnect from the plurality of metallization interconnects 142 and an die interconnect (e.g., 112b) from the plurality of die interconnects 112 may be free of a solder interconnect.

The at least one interconnection die 201 may be a dummy die. The at least one interconnection die 201 may be free of active components. The at least one interconnection die 201 may be free of transistors. One possible difference between the at least one interconnection die 201 and the at least one interconnection die 101 is that the at least one interconnection die 201 does not include a pad interconnect 112a, and a pad interconnect 112c. One advantage of not having the pad interconnect 112a and/or the pad interconnect 112c is that the at least one interconnection die 201 may be thinner than the at least one interconnection die 101, which can help reduce the overall thickness of the package. The at least one interconnection die 201 may be a means for die interconnection.

The pitch of interconnects between the metallization portion 102 and the metallization portion 104 may be relatively small. For example, the plurality of die interconnects 112 of the at least one interconnection die 201, may have a pitch between neighboring die interconnects in a range of about 150-270 micrometers. These dimensions are possible through the use of the at least one interconnection die 201, which (i) helps provide a package 200 that is thinner while still able to accommodate an integrated device between metallization portions, and (ii) helps provide interconnects in an encapsulation layer with low pitches (e.g., 150-270 micrometers), and thus helps provide high-density routing (e.g., high-density interconnects) in an encapsulation layer.

The integrated device 105 may be configured to be electrically coupled to the integrated device 103 through the plurality of solder interconnect 150, the plurality of metallization interconnects 142, the at least one interconnection die 201 (a plurality of interconnects 112), the plurality of solder interconnects 115, the plurality of metallization interconnects 122 and/or the plurality of solder interconnects 130.

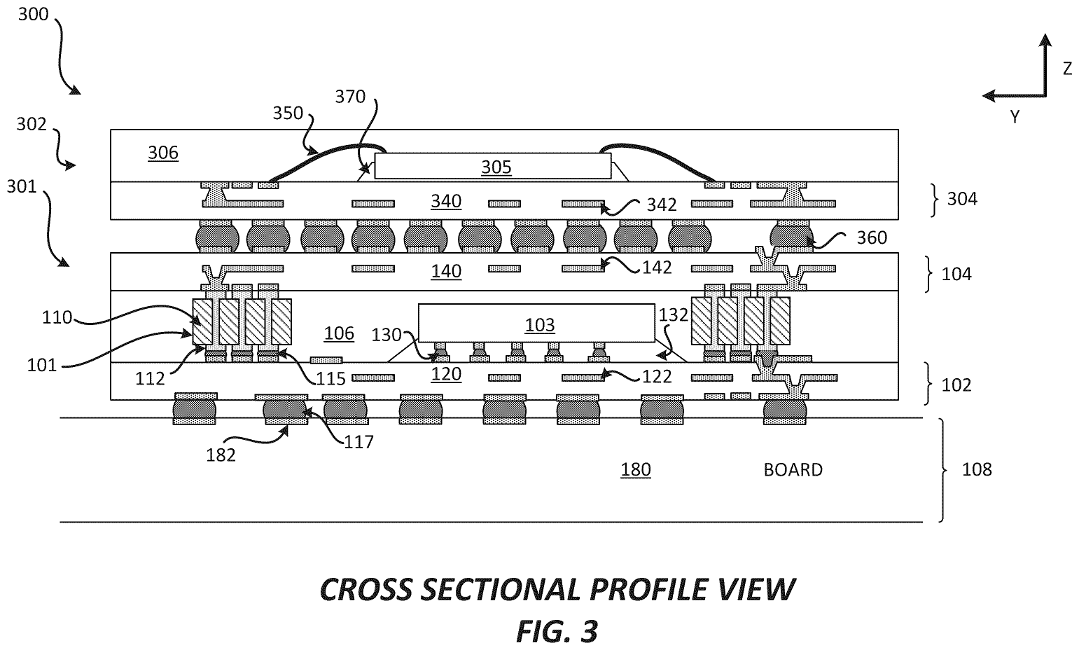

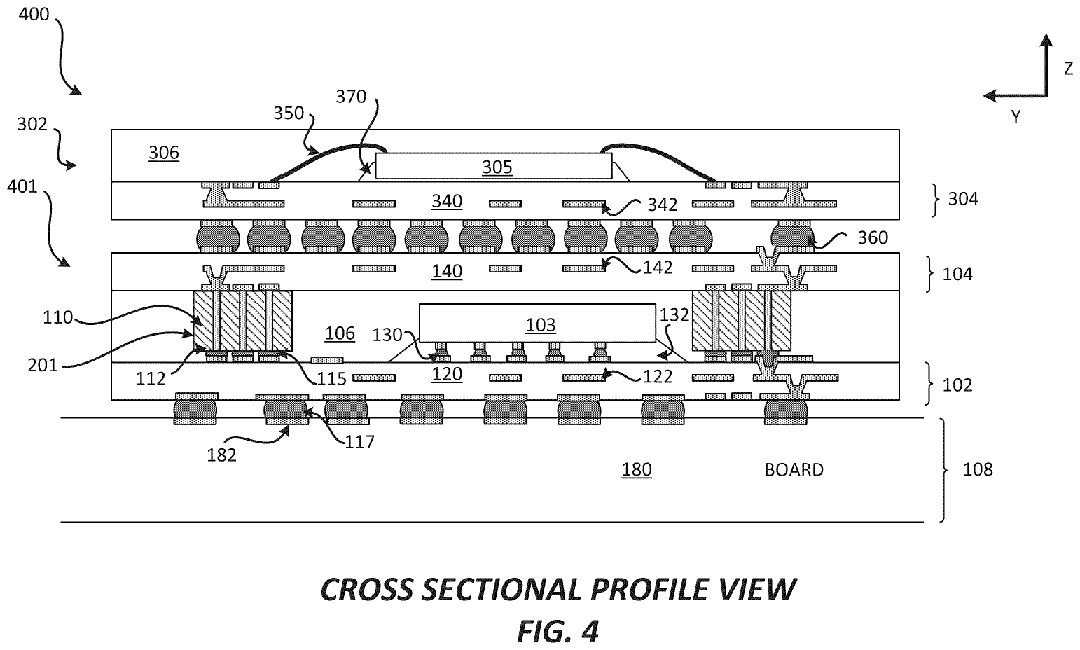

As will be further described below in at least FIGS. 3 and 4, in some implementations, another package (e.g., second package) may be coupled to the packages described in FIGS. 1 and 2. Thus, for example, as will be further described below, a package with an interconnection die may be a package on package (PoP) that includes a first package and a second package on top of the first package.

FIG. 3 illustrates a cross sectional profile view of a package 300 that includes a high density interconnection. The package 300 may include a package on package (PoP). The package 300 includes a package 301 and a package 302. The package 301 may be a first package and the package 302 may be a second package. The package 302 is coupled to the package 301 through a plurality of solder interconnects 360. The package 300 is coupled to the board 108 through the plurality of solder interconnects 117. The board 108 includes at least one board dielectric layer 180 and a plurality of board interconnects 182. The board 108 may include a printed circuit board (PCB). The package 300 is coupled to the plurality of board interconnects 182 of the board 108 through the plurality of solder interconnects 117.

The package 301 may be similar to the package 100 of FIG. 1. The package 301 may be configured and/or arranged in a similar manner as described for the package 100 of FIG. 1. The package 301 includes at least one interconnection die 101, the metallization portion 102, the metallization portion 104, the integrated device 103 and the encapsulation layer 106. The metallization portion 102 includes at least one dielectric layer 120 and a plurality of metallization interconnects 122. The metallization portion 102 (e.g., first metallization portion) includes a first side (e.g., front side) and a second side (e.g., back side). The metallization portion 104 (e.g., second metallization portion) includes at least one dielectric layer 140 and a plurality of metallization interconnects 142. The metallization portion 104 includes a first side (e.g., front side) and a second side (e.g., back side). The metallization portion 104 (e.g., second metallization portion) is coupled to the metallization portion 102 (e.g., first metallization portion) through the at least one interconnection die 101.

The package 302 includes a substrate 304, an integrated device 305, a plurality of wire bonds 350, an adhesive 370, and an encapsulation layer 306. The substrate 304 includes at least one dielectric layer 340 and a plurality of interconnects 342. The integrated device 305 is coupled to the substrate 304 through the adhesive 370. The plurality of wire bonds 350 is coupled to the integrated device 305 and the plurality of interconnects 342 of the substrate 304. The integrated device 305 may include a memory die. In some implementations, there may be several integrated devices 305 that are stacked on top of each other. The encapsulation layer 306 encapsulates the integrated device 305 and the plurality of wire bonds 350. The encapsulation layer 306 is coupled to the substrate 304 and the integrated device 305. The encapsulation layer 306 is located over the substrate 304 and the integrated device 305. The encapsulation layer 306 may include a mold, a resin and/or an epoxy. The encapsulation layer 306 may be a means for encapsulation. The encapsulation layer 306 may be provided by using a compression and transfer molding process, a sheet molding process, or a liquid molding process. The encapsulation layer 306 may be similar or the same as the encapsulation layer 106.

The integrated device 305 may be configured to be electrically coupled to the integrated device 103 through the plurality of wire bonds 350, the plurality of interconnects 342, the plurality of solder interconnects 360, the plurality of metallization interconnects 142, the at least one interconnection die 101 (a plurality of interconnects 112), the plurality of solder interconnects 115, the plurality of metallization interconnects 122 and/or the plurality of solder interconnects 130.

FIG. 4 illustrates a cross sectional profile view of a package 400 that includes a high density interconnection. The package 400 may include a package on package (PoP). The package 300 includes a package 401 and the package 302. The package 401 may be a first package and the package 302 may be a second package. The package 302 is coupled to the package 401 through a plurality of solder interconnects 360. The package 400 is coupled to the board 108 through the plurality of solder interconnects 117. The board 108 includes at least one board dielectric layer 180 and a plurality of board interconnects 182. The board 108 may include a printed circuit board (PCB). The package 400 is coupled to the plurality of board interconnects 182 of the board 108 through the plurality of solder interconnects 117.

The package 401 may be similar to the package 200 of FIG. 2. The package 401 may be configured and/or arranged in a similar manner as described for the package 200 of FIG. 2. The package 401 includes at least one interconnection die 201, the metallization portion 102, the metallization portion 104, the integrated device 103 and the encapsulation layer 106. The metallization portion 102 includes at least one dielectric layer 120 and a plurality of metallization interconnects 122. The metallization portion 102 (e.g., first metallization portion) includes a first side (e.g., front side) and a second side (e.g., back side). The metallization portion 104 (e.g., second metallization portion) includes at least one dielectric layer 140 and a plurality of metallization interconnects 142. The metallization portion 104 includes a first side (e.g., front side) and a second side (e.g., back side). The metallization portion 104 (e.g., second metallization portion) is configured to be coupled (e.g., electrically coupled) to the metallization portion 102 (e.g., first metallization portion) through the at least one interconnection die 101.

The package 302 includes the substrate 304, the integrated device 305, the plurality of wire bonds 350, the adhesive 370, and the encapsulation layer 306. The substrate 304 includes at least one dielectric layer 340 and a plurality of interconnects 342. The integrated device 305 is coupled to the substrate 304 through the adhesive 370. The plurality of wire bonds 350 is coupled to the integrated device 305 and the plurality of interconnects 342 of the substrate 304. The integrated device 305 may include a memory die. In some implementations, there may be several integrated devices 305 that are stacked on top of each other. The encapsulation layer 306 encapsulates the integrated device 305 and the plurality of wire bonds 350. The encapsulation layer 306 is coupled to the substrate 304 and the integrated device 305. The encapsulation layer 306 is located over the substrate 304 and the integrated device 305. The encapsulation layer 306 may include a mold, a resin and/or an epoxy. The encapsulation layer 306 may be a means for encapsulation. The encapsulation layer 306 may be provided by using a compression and transfer molding process, a sheet molding process, or a liquid molding process. The encapsulation layer 306 may be similar or the same as the encapsulation layer 106.

The integrated device 305 may be configured to be electrically coupled to the integrated device 103 through the plurality of wire bonds 350, the plurality of interconnects 342, the plurality of solder interconnects 360, the plurality of metallization interconnects 142, the at least one interconnection die 201 (a plurality of interconnects 112), the plurality of solder interconnects 115, the plurality of metallization interconnects 122 and/or the plurality of solder interconnects 130.

The plurality of metallization interconnects 122 and/or the plurality of metallization interconnects 142 may have a thickness in a range of about 3-7 micrometers. For example, one or more redistribution interconnects from the plurality of metallization interconnects 122 and/or from the plurality of metallization interconnects 142 may have a thickness that is in a range of about 3-7 micrometers. In some implementations, one or more trace interconnects (e.g., trace) from the plurality of interconnects 342 (from the substrate 204) may have a thickness in a range of about 10-15 micrometers.

An integrated device (e.g., 103, 105, 305) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 103, 105) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

The package (e.g., 100, 200, 300, 400) may be implemented in a radio frequency (RF) package. The RF package may be a radio frequency front end (RFFE) package. A package (e.g., 100, 200) may be configured to provide Wireless Fidelity (WiFi) communication and/or cellular communication (e.g., 2G, 3G, 4G, 5G). The packages (e.g., 100, 300) may be configured to support Global System for Mobile (GSM) Communications, Universal Mobile Telecommunications System (UMTS), and/or Long-Term Evolution (LTE). The packages (e.g., 100, 200) may be configured to transmit and receive signals having different frequencies and/or communication protocols.

Having described various interconnection die, a sequence for fabricating an interconnection die will now be described below.

### Exemplary Sequence for Fabricating an Interconnection Die

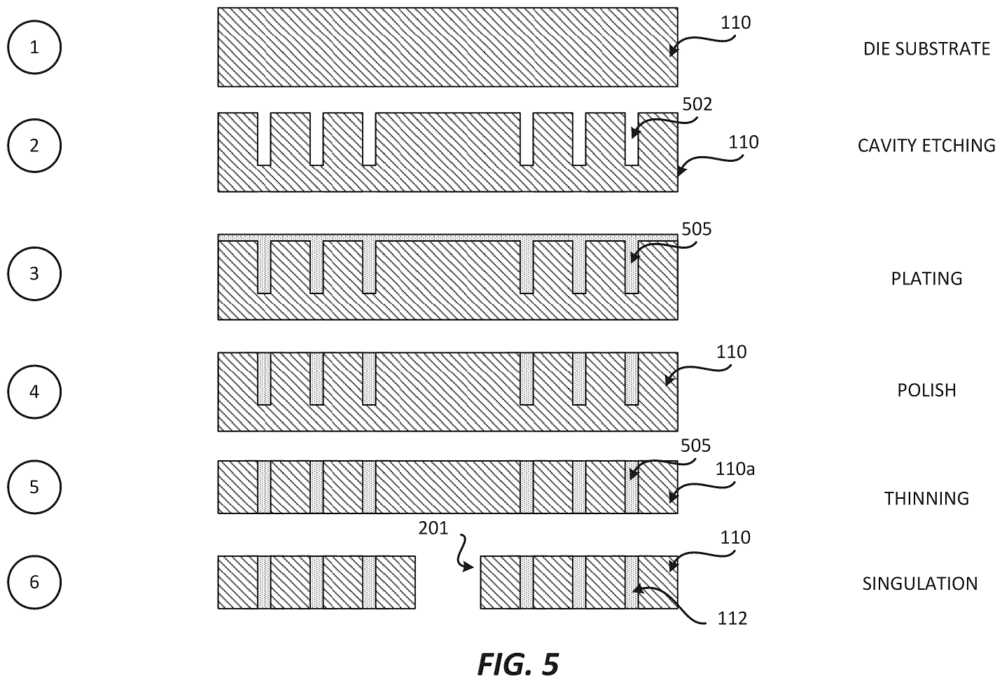

In some implementations, fabricating an interconnection die includes several processes. FIG. 5 illustrates an exemplary sequence for providing or fabricating an interconnection die. In some implementations, the sequence of FIG. 5 may be used to provide or fabricate the interconnection die 201. However, the process of FIG. 5 may be used to fabricate any of the interconnection die (e.g., 101) described in the disclosure.

It should be noted that the sequence of FIG. 5 may combine one or more stages in order to simplify and/or clarify the sequence for providing or fabricating an interconnection die. In some implementations, the order of the processes may be changed or modified. In some implementations, one or more of processes may be replaced or substituted without departing from the scope of the disclosure.

Stage 1, as shown in FIG. 5, illustrates a state after a die substrate 110 is provided. The die substrate 110 includes silicon. The die substrate 110 may include a first surface and a second surface. In some implementations, the first surface of the die substrate 110 may be a top surface and the second surface of the die substrate 110 may be a bottom surface. In some implementations, the first surface of the die substrate 110 may be a bottom surface and the second surface of the die substrate 110 may be a top surface.

Stage 2 illustrates a state after a plurality of cavities 502 are formed in the die substrate 110. For example, the plurality of cavities 502 may be formed through the first surface of the die substrate 110. The plurality of cavities 502 may include trenches. The plurality of cavities 502 may extend partially through the thickness of the die substrate 110. A laser ablation process and/or an etching process may be used to form the plurality of cavities 502.

Stage 3 illustrates after a metal layer 505 is formed in the plurality of cavities 502 and/or over the first surface of the die substrate 110. The metal layer 505 may include copper. A plating process may be used to form the metal layer 505.

Stage 4 illustrates a state after portions of the metal layer 505 are removed. For example, portions of the metal layer 505 that are coupled to the first surface of the die substrate 110 may be removed, leaving the metal layer 505 in the plurality of cavities 502. A polishing process may be used to remove portions of the metal layer 505. The remaining metal from the metal layer 505 that is located in the plurality of cavities 502 may define a plurality of interconnects 112b, as described in FIG. 1 and FIG. 2.

Stage 5 illustrates a state after the die substrate 110 is thinned. For example, portions (e.g., bottom portions) of the die substrate 110 may be removed, leaving at least the die substrate 110a, which exposes the bottom side of the metal layer 505. A grinding process may be used to remove portions of the die substrate 110. The grinding process may also remove portions of the metal layer 505 that are located in the plurality of cavities 502.

Stage 6 illustrates a state after singulation to form several interconnection dies. A mechanical process may be used to singulate the die substrate 110 into several interconnection dies (e.g., 101, 201). A saw may be used to singulate the die substrate 110. In some implementations. Stage 6 may illustrate one implementation of an interconnection die that includes interconnects, and no additional interconnects are formed in, above or below the die substrate 110.

### Exemplary Sequence for Fabricating an Interconnection Die

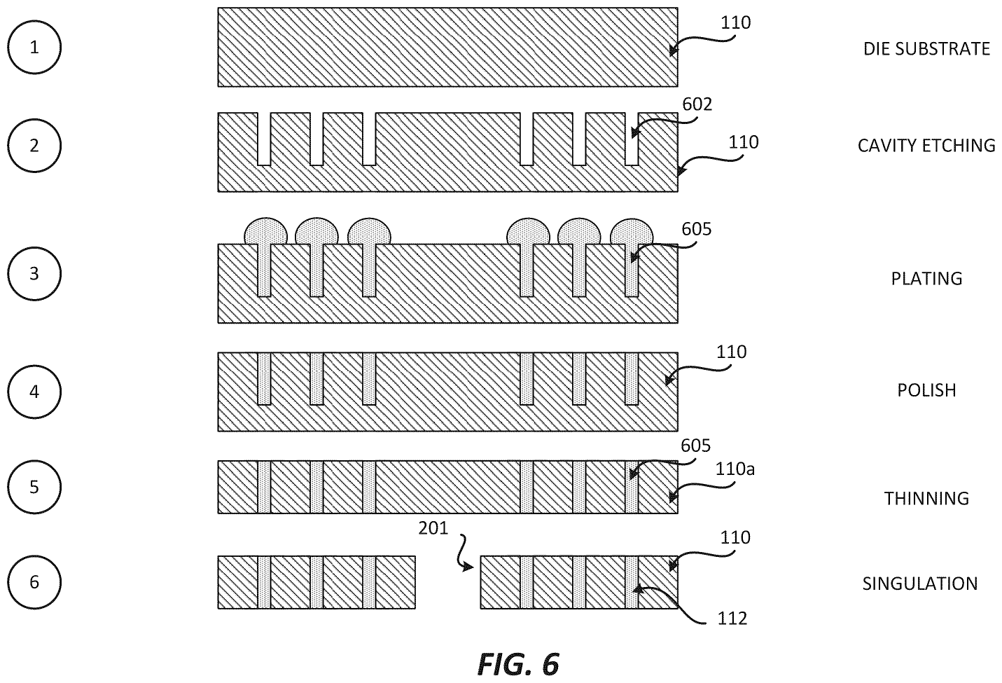

In some implementations, fabricating an interconnection die includes several processes. FIG. 6 illustrate an exemplary sequence for providing or fabricating an interconnection die. In some implementations, the sequence of FIG. 6 may be used to provide or fabricate the interconnection die 201. However, the process of FIG. 6 may be used to fabricate any of the interconnection die (e.g., 101) described in the disclosure.

It should be noted that the sequence of FIG. 6 may combine one or more stages in order to simplify and/or clarify the sequence for providing or fabricating an interconnection die. In some implementations, the order of the processes may be changed or modified. In some implementations, one or more of processes may be replaced or substituted without departing from the scope of the disclosure.

Stage 1, as shown in FIG. 6, illustrates a state after a die substrate 110 is provided. The die substrate 110 includes silicon. The die substrate 110 may include a first surface and a second surface. In some implementations, the first surface of the die substrate 110 may be a top surface and the second surface of the die substrate 110 may be a bottom surface. In some implementations, the first surface of the die substrate 110 may be a bottom surface and the second surface of the die substrate 110 may be a top surface.

Stage 2 illustrates a state after a plurality of cavities 602 are formed in the die substrate 110. For example, the plurality of cavities 602 may be formed through the first surface of the die substrate 110. The plurality of cavities 602 may include trenches. The plurality of cavities 602 may extend partially through the thickness of the die substrate 110. A laser ablation process and/or an etching process may be used to form the plurality of cavities 602.

Stage 3 illustrates after a metal layer 605 is formed in the plurality of cavities 602 and/or over the first surface of the die substrate 110. The metal layer 605 may include copper. A fill process may be used to form the metal layer 605, where a conductive paste may be used to fill the plurality of cavities 602. Additional metal layer 605 may be located over the die substrate 110.

Stage 4 illustrates a state after portions of the metal layer 605 are removed. For example, portions of the metal layer 605 that are coupled to the first surface of the die substrate 110 may be removed, leaving the metal layer 605 in the plurality of cavities 602. A polishing process may be used to remove portions of the metal layer 605. The remaining metal from the metal layer 605 that is located in the plurality of cavities 602 may define a plurality of interconnects 112b, as described in FIG. 1 and FIG. 2.

Stage 5 illustrates a state after the die substrate 110 is thinned. For example, portions (e.g., bottom portions) of the die substrate 110 may be removed, leaving at least the die substrate 110a, which exposes the bottom side of the metal layer 605. A grinding process may be used to remove portions of the die substrate 110. The grinding process may also remove portions of the metal layer 605 that are located in the plurality of cavities 602.

Stage 6 illustrates a state after singulation to form several interconnection dies. A mechanical process may be used to singulate the die substrate 110 into several interconnection dies (e.g., 101, 201). A saw may be used to singulate the die substrate 110. In some implementations. Stage 6 may illustrate one implementation of an interconnection die that includes interconnects, and no additional interconnects are formed in, above or below the die substrate 110.

### Exemplary Sequence for Fabricating an Interconnection Die

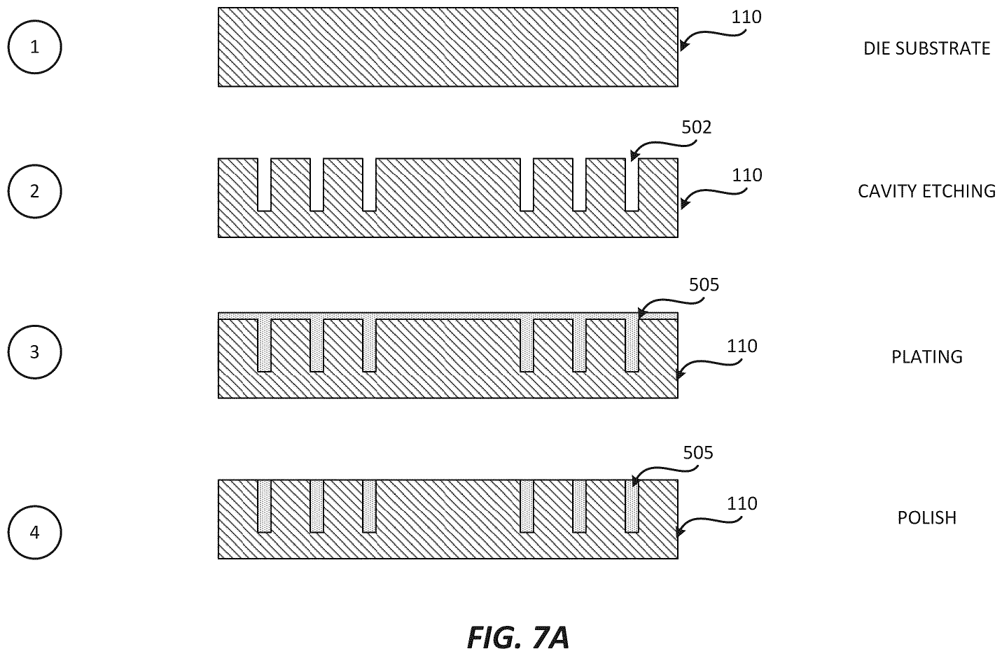

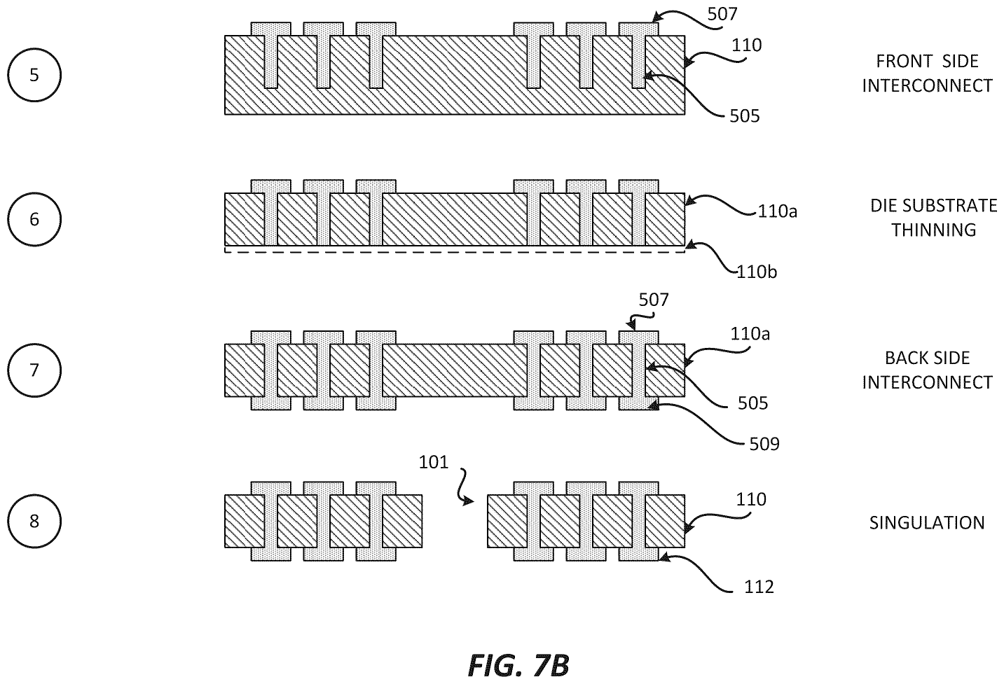

In some implementations, fabricating an interconnection die includes several processes. FIGS. 7A-7B illustrate an exemplary sequence for providing or fabricating an interconnection die. In some implementations, the sequence of FIGS. 7A-7B may be used to provide or fabricate the interconnection die 101. However, the process of FIGS. 7A-7B may be used to fabricate any of the interconnection die (e.g., 201) described in the disclosure.

It should be noted that the sequence of FIGS. 7A-7B may combine one or more stages in order to simplify and/or clarify the sequence for providing or fabricating an interconnection die. In some implementations, the order of the processes may be changed or modified. In some implementations, one or more of processes may be replaced or substituted without departing from the scope of the disclosure.

Stage 1, as shown in FIG. 7A, illustrates a state after a die substrate 110 is provided. The die substrate 110 includes silicon. The die substrate 110 may include a first surface and a second surface. In some implementations, the first surface of the die substrate 110 may be a top surface and the second surface of the die substrate 110 may be a bottom surface. In some implementations, the first surface of the die substrate 110 may be a bottom surface and the second surface of the die substrate 110 may be a top surface.

Stage 2 illustrates a state after a plurality of cavities 502 are formed in the die substrate 110. For example, the plurality of cavities 502 may be formed through the first surface of the die substrate 110. The plurality of cavities 502 may include trenches. The plurality of cavities 502 may extend partially through the thickness of the die substrate 110. A laser ablation process and/or an etching process may be used to form the plurality of cavities 502.

Stage 3 illustrates after a metal layer 505 is formed in the plurality of cavities 502 and/or over the first surface of the die substrate 110. The metal layer 505 may include copper. A plating process may be used to form the metal layer 505.

Stage 4 illustrates a state after portions of the metal layer 505 are removed. For example, portions of the metal layer 505 that are coupled to the first surface of the die substrate 110 may be removed, leaving the metal layer 505 in the plurality of cavities 502. A polishing process may be used to remove portions of the metal layer 505. The remaining metal from the metal layer 505 that is located in the plurality of cavities 502 may define a plurality of interconnects 112b, as described in FIG. 1 and FIG. 2.

Stage 5, as shown in FIG. 7B, illustrates a state after a metal layer 507 is formed over the first surface of the die substrate 110. A plating process may be used to form the metal layer 507. The metal layer 507 may be coupled to the metal layer 505. The metal layer 507 may define a plurality of interconnects 112b, as described in FIG. 1 and FIG. 2. The metal layer 507 may represent the front side interconnects of an interconnection die.

Stage 6 illustrates a state after the die substrate 110 is thinned. For example, portions (e.g., bottom portions) of the die substrate 110 may be removed, leaving at least the die substrate 110a, which exposes the bottom side of the metal layer 505. In some implementations, portions of the die substrate 110 may be removed, leaving at least the die substrate 110a and the die substrate 110b. When the die substrate 110b is present, the bottom side of the metal layer 505 is not exposed. A grinding process may be used to remove portions (e.g., bottom portions) of the die substrate 110. The grinding process may also remove portions of the metal layer 505 that are located in the plurality of cavities 502. In some implementations, Stage 6 may illustrate one implementation of interconnection die that includes interconnects, and no additional interconnects are formed in, above or below the die substrate 110. If no further interconnects are formed, singulation may occur in a similar manner as described below at Stage 8. As will be further described below, the interconnection die that is shown in Stage 6 may be used to couple to a substrate.

Stage 7 illustrates a state after a metal layer 509 is formed over the second surface of the die substrate 110. A plating process may be used to form the metal layer 509. The metal layer 509 may be coupled to the metal layer 505. The metal layer 507 may define a plurality of interconnects 112c, as described in FIG. 1 and FIG. 2. The metal layer 509 may represent the back side interconnects of an interconnection die.

Stage 8 illustrates a state after singulation to form several interconnection dies. A mechanical process may be used to singulate the die substrate 110 into several interconnection dies (e.g., 101, 201). A saw may be used to singulate the die substrate 110.

### Exemplary Sequence for Fabricating an Interconnection Die

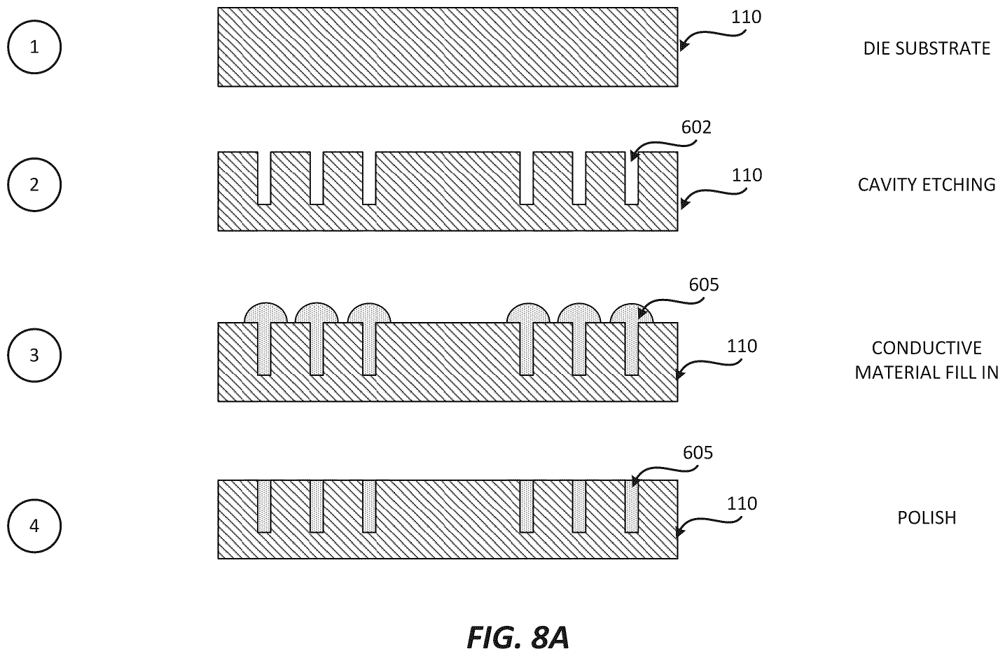

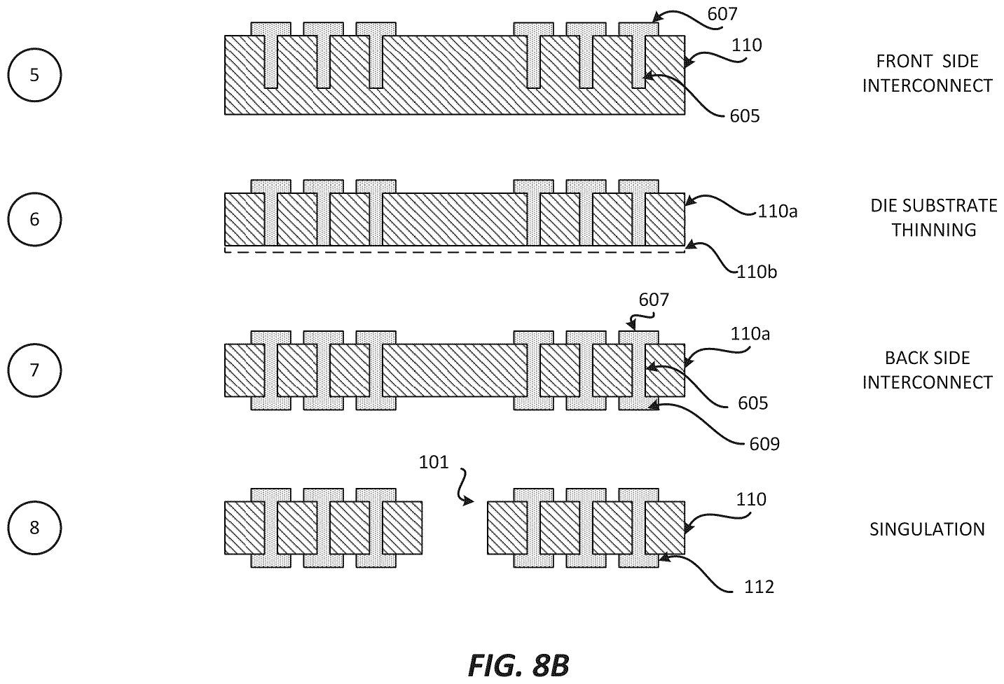

In some implementations, fabricating an interconnection die includes several processes. FIGS. 8A-8B illustrate an exemplary sequence for providing or fabricating an interconnection die. In some implementations, the sequence of FIGS. 8A-8B may be used to provide or fabricate the interconnection die 101. However, the process of FIGS. 8A-8B may be used to fabricate any of the interconnection die (e.g., 201) described in the disclosure.

It should be noted that the sequence of FIGS. 8A-8B may combine one or more stages in order to simplify and/or clarify the sequence for providing or fabricating an interconnection die. In some implementations, the order of the processes may be changed or modified. In some implementations, one or more of processes may be replaced or substituted without departing from the scope of the disclosure.

Stage 1, as shown in FIG. 8A, illustrates a state after a die substrate 110 is provided. The die substrate 110 includes silicon. The die substrate 110 may include a first surface and a second surface. In some implementations, the first surface of the die substrate 110 may be a top surface and the second surface of the die substrate 110 may be a bottom surface. In some implementations, the first surface of the die substrate 110 may be a bottom surface and the second surface of the die substrate 110 may be a top surface.

Stage 2 illustrates a state after a plurality of cavities 602 are formed in the die substrate 110. For example, the plurality of cavities 602 may be formed through the first surface of the die substrate 110. The plurality of cavities 602 may include trenches. The plurality of cavities 602 may extend partially through the thickness of the die substrate 110. A laser ablation process and/or an etching process may be used to form the plurality of cavities 602.

Stage 3 illustrates after a metal layer 605 is formed in the plurality of cavities 602 and/or over the first surface of the die substrate 110. The metal layer 605 may include copper. A fill process may be used to form the metal layer 605, where a conductive paste may be used to fill the plurality of cavities 602. The metal layer 605 may be located over the die substrate 110.

Stage 4 illustrates a state after portions of the metal layer 605 are removed. For example, portions of the metal layer 605 that are coupled to the first surface of the die substrate 110 may be removed, leaving the metal layer 605 in the plurality of cavities 602. A polishing process may be used to remove portions of the metal layer 605. The remaining metal from the metal layer 605 that is located in the plurality of cavities 602 may define a plurality of interconnects 112b, as described in FIG. 1 and FIG. 2.

Stage 5, as shown in FIG. 8B, illustrates a state after a metal layer 607 is formed over the first surface of the die substrate 110. A plating process may be used to form the metal layer 607. The metal layer 607 may be coupled to the metal layer 605. The metal layer 607 may define a plurality of interconnects 112a, as described in FIG. 1 and FIG. 2. The metal layer 607 may represent the front side interconnects of an interconnection die.

Stage 6 illustrates a state after the die substrate 110 is thinned. For example, portions (e.g., bottom portions) of the die substrate 110 may be removed, leaving at least the die substrate 110a, which exposes the bottom side of the metal layer 605. In some implementations, portions of the die substrate 110 may be removed, leaving at least the die substrate 110a and the die substrate 110b. When the die substrate 110b is present, the bottom side of the metal layer 605 is not exposed. A grinding process may be used to remove portions (e.g., bottom portions) of the die substrate 110. The grinding process may also remove portions of the metal layer 605 that are located in the plurality of cavities 602. In some implementations, Stage 6 may illustrate one implementation of interconnection die that includes interconnects, and no additional interconnects are formed in, above or below the die substrate 110. If no further interconnects are formed, singulation may occur in a similar manner as described below at Stage 8. As will be further described below, the interconnection die that is shown in Stage 6 may be used to couple to a substrate.

Stage 7 illustrates a state after a metal layer 609 is formed over the second surface of the die substrate 110. A plating process may be used to form the metal layer 609. The metal layer 609 may be coupled to the metal layer 605. The metal layer 609 may define a plurality of interconnects 112c, as described in FIG. 1 and FIG. 2. The metal layer 609 may represent the back side interconnects of an interconnection die.

Stage 8 illustrates a state after singulation to form several interconnection dies. A mechanical process may be used to singulate the die substrate 110 into several interconnection dies (e.g., 101, 201). A saw may be used to singulate the die substrate 110.

### Exemplary Flow Diagram of a Method for Fabricating an Interconnection Die

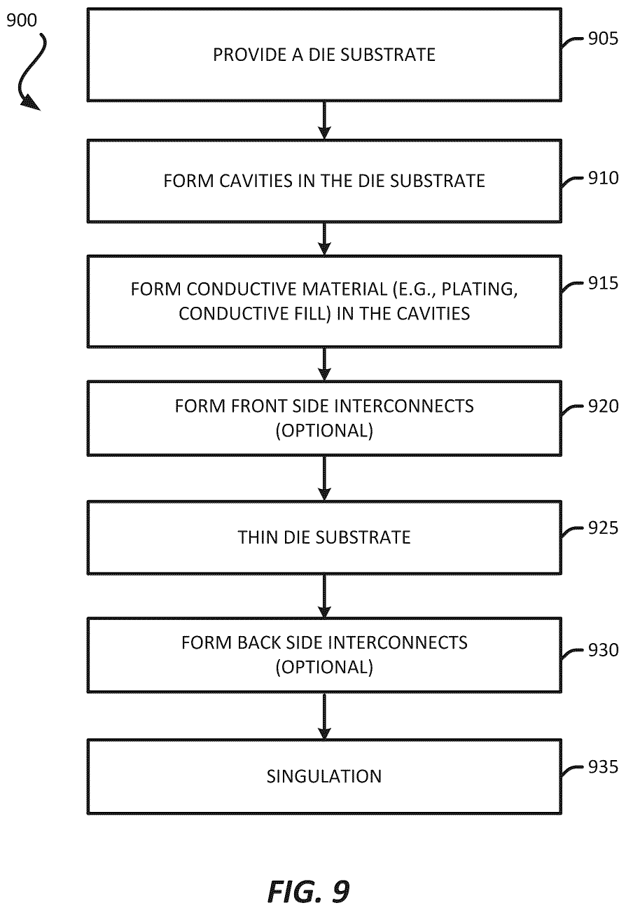

In some implementations, fabricating an interconnection die includes several processes. FIG. 9 illustrates an exemplary flow diagram of a method 900 for providing or fabricating an interconnection die. In some implementations, the method 900 of FIG. 9 may be used to provide or fabricate the interconnection die 101 described in the disclosure. However, the method 900 may be used to provide or fabricate any of the interconnection die (e.g., 201) described in the disclosure.

It should be noted that the method 900 of FIG. 9 may combine one or more processes in order to simplify and/or clarify the method for providing or fabricating an interconnection die. In some implementations, the order of the processes may be changed or modified.

The method provides (at 905) a die substrate (e.g., 110). The die substrate 110 includes silicon. The die substrate 110 may include a first surface and a second surface. In some implementations, the first surface of the die substrate 110 may be a top surface and the second surface of the die substrate 110 may be a bottom surface. In some implementations, the first surface of the die substrate 110 may be a bottom surface and the second surface of the die substrate 110 may be a top surface. Stage 1 of FIG. 7A illustrates and describes an example of providing a die substrate. Stage 1 of FIG. 8A illustrates and describes an example of providing a die substrate.

The method forms (at 910) a plurality of cavities (e.g., 502, 602) in the die substrate 110. For example, the plurality of cavities (e.g., 502, 602) may be formed through the first surface of the die substrate 110. The plurality of cavities (e.g., 502, 602) may include trenches. The plurality of cavities (e.g., 502, 602) may extend partially through the thickness of the die substrate 110. A laser ablation process and/or an etching process may be used to form the plurality of cavities (e.g., 502, 602). Stage 2 of FIG. 7A illustrates and describes an example of forming cavities in a die substrate. Stage 2 of FIG. 8A illustrates and describes an example of forming cavities in a die substrate.

The method forms (at 915) a conductive material (e.g., electrically conductive material) in the plurality of cavities (e.g., 502, 602) of the die substrate 110. The conductive material may include a metal layer (e.g., 505, 605). The conductive material may be formed over the surface of the die substrate 110. The conductive material may include copper. A plating process may be used to form the conductive material. A fill process may be used to form the conductive material. Stage 3 of FIG. 7A illustrates and describes an example of forming conductive materials in a die substrate. Stage 3 of FIG. 8A illustrates and describes an example of forming conductive materials in a die substrate. In some implementations forming the conductive material may include removing portions of the conductive material. A polishing process may be used to remove portions of the conductive material. Removing portions of the conductive material may include removing portions of the conductive material that is coupled to the first surface of the die substrate 110 and leaving the conductive material that is located in the plurality of cavities (e.g., 502, 602) of the die substrate 110. Stage 4 of FIG. 7A illustrates and describes an example of removing portions of conductive materials in a die substrate. Stage 4 of FIG. 8A illustrates and describes an example of removing portions of conductive materials in a die substrate.

The method optionally forms (at 920) a plurality of front side interconnects. The front side interconnects may be coupled to the top side of the die substrate 110. The plurality of front side interconnects may be defined by a patterned metal layer (e.g., 507, 607) on a top surface of the die substrate 110. A plating process may be used to form the metal layer (e.g., 507, 607). The metal layer 507 may be coupled to the metal layer 505. The metal layer 607 may be coupled to the metal layer 605. The metal layer 607 may define a plurality of interconnects 112a, as described in FIG. 1 and FIG. 2. The metal layer 607 may represent the front side interconnects of an interconnection die. The plurality of interconnects 112a may represent the plurality of front side interconnects of an interconnection die. Stage 5 of FIG. 7B illustrates and describes an example of forming front side interconnects. Stage 5 of FIG. 8B illustrates and describes an example of forming front side interconnects.

The method thins (at 925) the die substrate (e.g., 110). Different implementations may thin the die substrate 110 differently. For example, some implementations may thin the die substrate 110 such that a bottom side of the metal layer (e.g., 505, 605) is exposed. Some implementations may thin the die substrate 110 without exposing the bottom side of the metal layer (e.g., 505, 605). A grinding process may be used to remove portions (e.g., bottom portions) of the die substrate 110. The grinding process may also remove portions of the metal layer (e.g., 505, 605) that are located in the plurality of cavities (e.g., 502, 602). Stage 6 of FIG. 7B illustrates and describes an example of thinning a die substrate. Stage 6 of FIG. 8B illustrates and describes an example of thinning a die substrate.

The method optionally forms (at 930) a plurality of back side interconnects. The back side interconnects may be coupled to the bottom side of the die substrate 110. The plurality of back side interconnects may be defined by a patterned metal layer (e.g., 509, 609) on a bottom surface of the die substrate 110. A plating process may be used to form the metal layer (e.g., 509, 609). The metal layer 509 may be coupled to the metal layer 505. The metal layer 609 may be coupled to the metal layer 605. The metal layer 609 may define a plurality of interconnects 112c, as described in FIG. 1 and FIG. 2. The metal layer 609 may represent the back side interconnects of an interconnection die. The plurality of interconnects 112c may represent the plurality of back side interconnects of an interconnection die. Stage 7 of FIG. 7B illustrates and describes an example of forming back side interconnects. Stage 7 of FIG. 8B illustrates and describes an example of forming back side interconnects.

The method singulates (at 935) the die substrate 110 to form several interconnection dies (e.g., 101, 201). A mechanical process may be used to singulate the die substrate 110 into several interconnection dies (e.g., 101, 201). A saw may be used to singulate the die substrate 110. Stage 8 of FIG. 7B illustrates and describes an example of singulation. Stage 8 of FIG. 8B illustrates and describes an example of singulation.

### Exemplary Sequence for Fabricating a Package Comprising an Interconnection Die

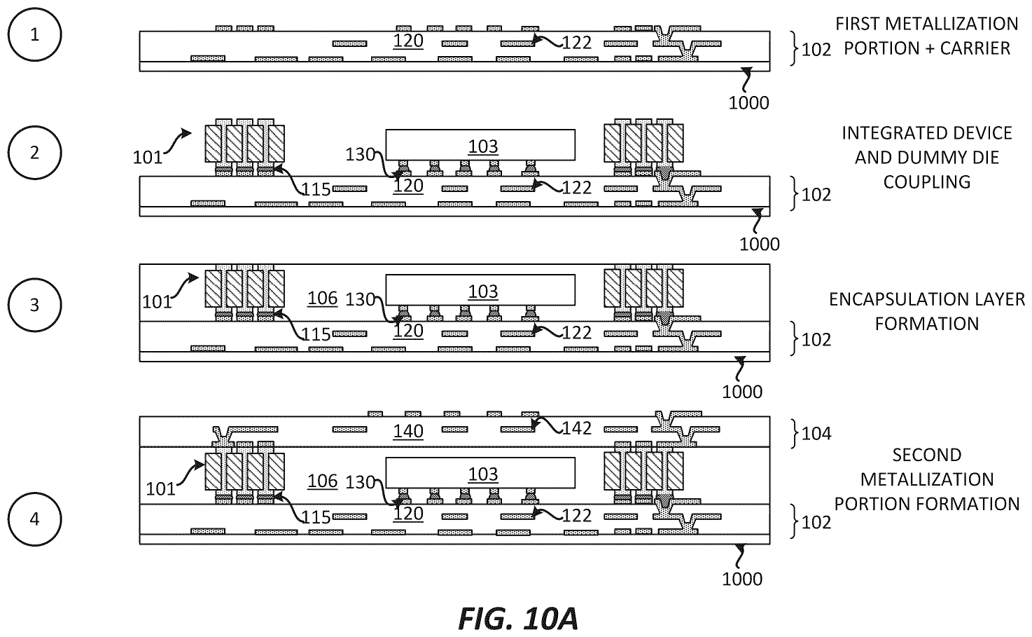

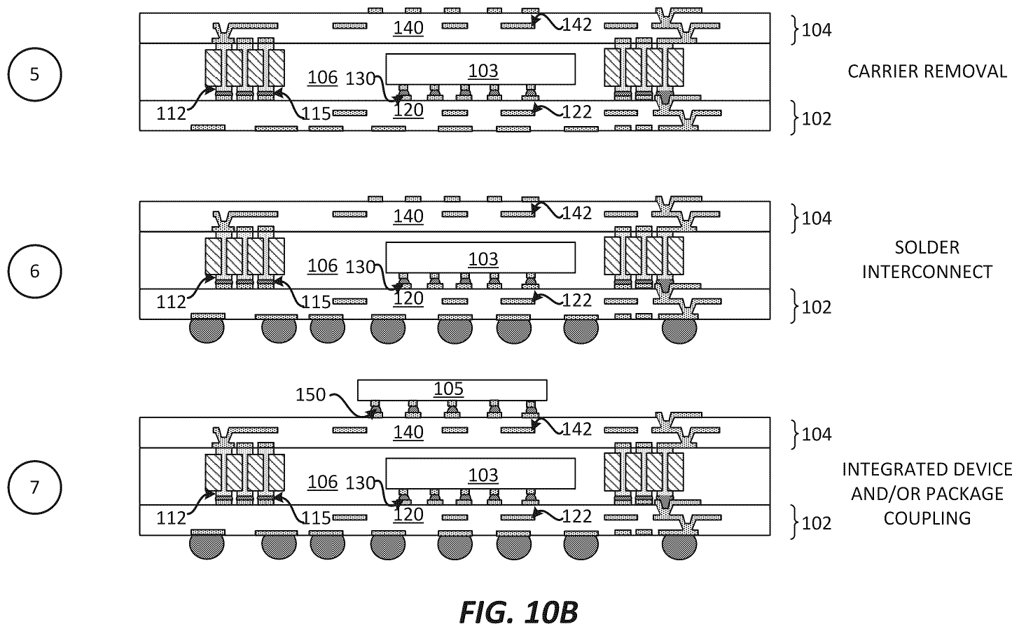

In some implementations, fabricating a package includes several processes. FIGS. 10A-10B illustrate an exemplary sequence for providing or fabricating a package. In some implementations, the sequence of FIGS. 10A-10B may be used to provide or fabricate the package 100. However, the process of FIGS. 10A-10B may be used to fabricate any of the packages (e.g., 200, 300, 301, 302, 400, 401) described in the disclosure.

It should be noted that the sequence of FIGS. 10A-10B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

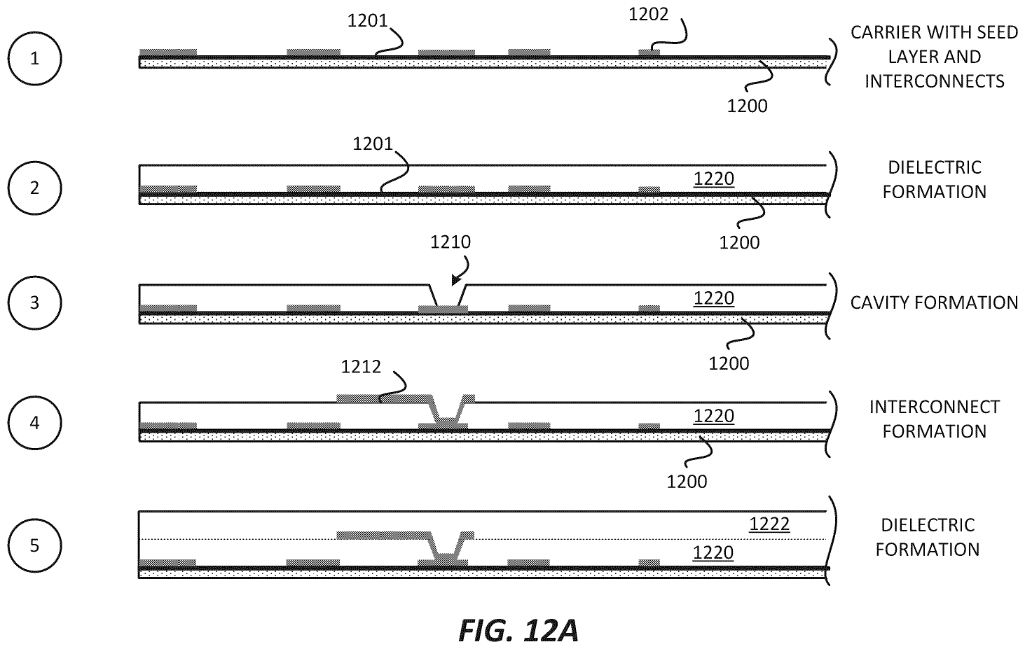

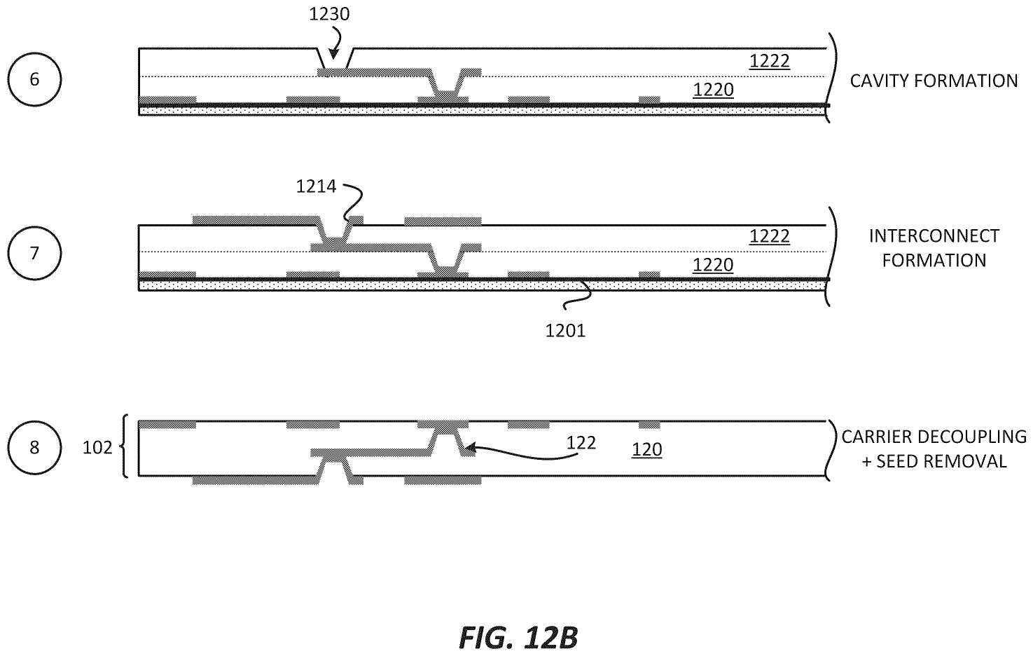

Stage 1, as shown in FIG. 10A, illustrates a state after a metallization portion 102 is provided. The metallization portion 102 may be provided over a carrier 1000. The metallization portion 102 includes at least one dielectric layer 120 and a plurality of metallization interconnects 122. The metallization portion 102 may include a first side (e.g., front side) and a second side (e.g., back side). The metallization portion 102 may include a redistribution portion. The metallization portion 102 may be fabricated using the method as described in FIGS. 12A-12B.

Stage 2 illustrates a state after an integrated device 103 is coupled to the first side (e.g., front side) of the metallization portion 102. The integrated device 103 may be coupled to the metallization portion 102 through the plurality of solder interconnects 130. The integrated device 103 may be coupled to the metallization portion 102 through a plurality of pillar interconnects and/or a plurality of solder interconnects 130. A solder reflow process may be used to couple the integrated device 103 to the metallization portion 102. Stage 2 also illustrates a state after at least one interconnection die 101 is coupled to the first side of the metallization portion 102. The at least one interconnection die 101 may be coupled to the metallization portion 102 through the plurality of solder interconnects 115. A solder reflow process may be used to couple the at least one interconnection die 101 to the metallization portion 102.

Stage 3 illustrates a state after an encapsulation layer 106 is provided over the metallization portion 102, the integrated device 103 and the at least one interconnection die 101. The encapsulation layer 106 may encapsulate the integrated device 103 and the at least one interconnection die 101. The encapsulation layer 106 may be coupled to the first side of the metallization portion 102. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process. In some implementations, a polishing process and/or a grinding process may be performed on the encapsulation layer 106 to at least flatten the surface of the encapsulation layer 106.

Stage 4 illustrates a state after the metallization portion 104 formed over the encapsulation layer 106. The metallization portion 104 may be formed such that at least one dielectric layer 140 and a plurality of metallization interconnects 142 are formed. The metallization portion 104 may be formed such that the metallization portion 104 is coupled (e.g., electrically coupled) to the metallization portion 102 through the at least one interconnection die 101. The metallization portion 104 may be formed layer by layer over the encapsulation layer 106 and the interconnection die 101. The metallization portion 104 may include a first side (e.g., front side) and a second side (e.g., back side). The metallization portion 104 may be fabricated using a method that is the same and/or similar to the method as described in FIGS. 12A-12B. Instead of a carrier, the metallization portion 104 is fabricated and/or formed over a surface of the encapsulation layer 106 and/or a surface of the interconnection die 101. The at least one interconnection die 101 may be coupled to the metallization portion 104. Since the metallization portion 104 is formed over the at least one interconnection die 101, a solder interconnect is not needed to couple the metallization portion 104 to the at least one interconnection die 101. Thus, a coupling between an interconnect from the plurality of metallization interconnects 142 and an die interconnect (e.g., 112a) from the plurality of die interconnects 112 may be free of a solder interconnect. The integrated device 103 and the at least one interconnection die 101 may be located between the metallization portion 102 and the metallization portion 104.

Stage 5, as shown in FIG. 10B, illustrates a state after the carrier 1000 is removed from the metallization portion 102. A grinding process may be used to remove the carrier 1000 from the metallization portion 102. However, other processes may be used to decouple the carrier 1000 from the metallization portion 102.

Stage 6 illustrates a state after a plurality of solder interconnects 117 is coupled to the metallization portion 102. The plurality of solder interconnects 117 may be coupled to the second side (e.g., back side) of the metallization portion 102. A solder reflow process may be used to couple the plurality of solder interconnects 117 to the plurality of metallization interconnects 122 of the metallization portion 102.

Stage 7 illustrates a state after the integrated device 105 is coupled to the first side (e.g., front side) of the metallization portion 104. The integrated device 105 may be coupled to the metallization portion 104 through a plurality of pillar interconnects and/or a plurality of solder interconnects 150. A solder reflow process may be used to couple the integrated devices (and/or the passive devices) to the metallization portion 104 through a plurality of solder interconnects. It is noted that instead of an integrated device, another package, such as the package 302 may be coupled to the first side (e.g., front side) of the metallization portion 104.

### Exemplary Flow Diagram of a Method for Fabricating a Package Comprising an Interconnection Die

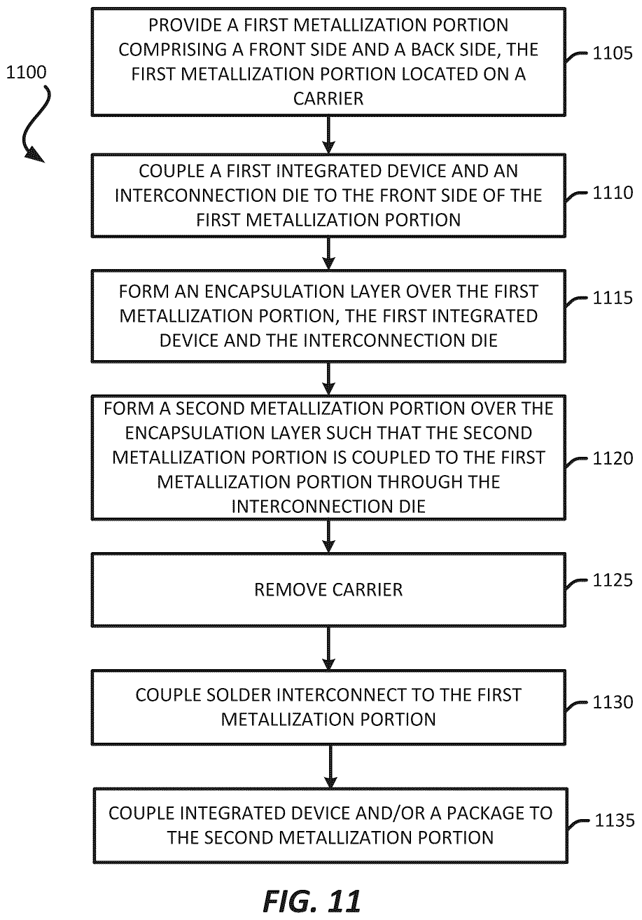

In some implementations, fabricating a package includes several processes. FIG. 11 illustrates an exemplary flow diagram of a method 1100 for providing or fabricating a package. In some implementations, the method 1100 of FIG. 11 may be used to provide or fabricate the package 100 described in the disclosure. However, the method 1100 may be used to provide or fabricate any of the packages (e.g., 200, 300, 301, 302, 400, 401) described in the disclosure.

It should be noted that the method 1100 of FIG. 11 may combine one or more processes in order to simplify and/or clarify the method for providing or fabricating a package. In some implementations, the order of the processes may be changed or modified.

The method provides (at 1105) a metallization portion (e.g., 102). The metallization portion 102 includes at least one dielectric layer 120 and a plurality of metallization interconnects 122. The metallization portion 102 (e.g., first metallization portion) may include a first side (e.g., front side) and a second side (e.g., back side). The metallization portion 102 may be fabricated using the method as described in FIGS. 12A-12B. Stage 1 of FIG. 10A illustrates and describes an example of providing a metallization portion.

The method couples (at 1110) an integrated device (e.g., 103) and at least one interconnection die (e.g., 101, 201) to the first side (e.g., front side) of the metallization portion 102. The integrated device 103 may be coupled to the metallization portion 102 through a plurality of pillar interconnects and/or the plurality of solder interconnects 130. A solder reflow process may be used to couple the integrated device 103 to the metallization portion 102. The at least one interconnection die 101 may be coupled to the metallization portion 102 through the plurality of solder interconnects 115. A solder reflow process may be used to couple the at least one interconnection die 101 to the metallization portion 102. Stage 2 of FIG. 10A illustrates and describes an example of coupling an integrated device and an interconnection die to a metallization portion.

The method forms (at 1115) an encapsulation layer (e.g., 106) over the metallization portion 102, the integrated device 103 and the at least one interconnection die 101. The encapsulation layer 106 may encapsulate the integrated device 103 and the at least one interconnection die 101. The encapsulation layer 106 may be coupled to the front side of the metallization portion 102. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process. In some implementations, a polishing process and/or a grinding process may be perform to at least flatten the surface of the encapsulation layer 106. Stage 3 of FIG. 10A illustrates and describes an example of providing an encapsulation layer.

The method forms (at 1120) a metallization portion (e.g., 104) over the encapsulation layer 106. The metallization portion 104 (e.g., second metallization portion) may be formed such that the metallization portion 104 is configured to be coupled (e.g., electrically coupled) the metallization portion (e.g., 102) through the at least one interconnection die (e.g., 101, 201). The metallization portion 104 includes at least one dielectric layer 140 and a plurality of metallization interconnects 142. The metallization portion 104 may include a first side (e.g., front side) and a second side (e.g., back side). The metallization portion 104 may be fabricated using the method as described in FIGS. 12A-12B. The metallization portion 104 may be coupled to the at least one interconnection die 101. The metallization portion 104 may be formed such that the at least one interconnection die 101 and the integrated device 103 are located between the metallization portion 102 and the metallization portion 104. Stage 4 of FIG. 10A illustrates and describes an example of forming a metallization portion over an encapsulation layer.

The method removes (at 1125) the carrier (e.g., 1000) from the metallization portion 102. A grinding process may be used to remove the carrier 1000 from the metallization portion 102. However, other processes may be used to decouple the carrier 1000 from the metallization portion 102. Stage 5 of FIG. 10B illustrates and describes an example of removing a carrier.

The method couples (at 1130) a plurality of solder interconnects (e.g., 117) to the metallization portion 102. A solder reflow process may be used to couple the plurality of solder interconnects 117 to the second surface of the metallization portion 102. Stage 6 of FIG. 10B illustrates and describes an example of coupling solder interconnects to a metallization portion.

The method couples (at 1135) an integrated device (e.g., 105) and/or a package (e.g., 302) to the first side (e.g., front side) of the metallization portion 104. The integrated device 105 may be coupled to the metallization portion 104 through a plurality of pillar interconnects and a plurality of solder interconnects 150. A solder reflow process may be used to couple the integrated device(s) (and/or the passive devices) to the metallization portion 104. It is noted that in addition or instead of an integrated device, another package, such as the package 302 may be coupled to the first side (e.g., front side) of the metallization portion 104. Stage 7 of FIG. 10B illustrates and describes an example of coupling an integrated device to a metallization portion.

In some implementations, several packages are fabricated at the same time. In such cases, the method may singulate the package (e.g., 100, 200, 300, 301, 302, 400, 402).

### Exemplary Sequence for Fabricating a Metallization Portion

In some implementations, fabricating a metallization portion includes several processes. FIGS. 12A-12B illustrate an exemplary sequence for providing or fabricating a metallization portion. In some implementations, the sequence of FIGS. 12A-12B may be used to provide or fabricate the metallization portion 102. However, the process of FIGS. 12A-12B may be used to fabricate any of the metallization portions (e.g., 104) described in the disclosure.

It should be noted that the sequence of FIGS. 12A-12B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 12A, illustrates a state after a carrier 1200 is provided. A seed layer 1201 and interconnects 1202 may be located over the carrier 1200. The interconnects 1202 may be located over the seed layer 1201. A plating process and etching process may be used to form the interconnects 1202. In some implementations, the carrier 1200 may be provided with the seed layer 1201 and a metal layer that is patterned to form the interconnects 1202. The interconnects 1202 may represent at least some of the metallization interconnects from the plurality of metallization interconnects 122.

Stage 2 illustrates a state after a dielectric layer 1220 is formed over the carrier 1200, the seed layer 1201 and the interconnects 1202. A deposition and/or lamination process may be used to form the dielectric layer 1220. The dielectric layer 1220 may include prepreg and/or polyimide. The dielectric layer 1220 may include a photo-imageable dielectric. However, different implementations may use different materials for the dielectric layer.

Stage 3 illustrates a state after a plurality of cavities 1210 is formed in the dielectric layer 1220. The plurality of cavities 1210 may be formed using an etching process (e.g., photo etching process) or laser process.

Stage 4 illustrates a state after interconnects 1212 are formed in and over the dielectric layer 1220, including in and over the plurality of cavities 1210. For example, a via, pad and/or traces may be formed. A plating process may be used to form the interconnects. Stage 4 illustrates that some portions of the interconnects 1212 may have a U-shape or a V-shape. The terms “U-shape” and” V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

Stage 5 illustrates a state after a dielectric layer 1222 is formed over the dielectric layer 1220 and the interconnects 1212. A deposition and/or lamination process may be used to form the dielectric layer 1222. The dielectric layer 1222 may include prepreg and/or polyimide. The dielectric layer 1222 may include a photo-imageable dielectric. However, different implementations may use different materials for the dielectric layer.

Stage 6, as shown in FIG. 12B, illustrates a state after a plurality of cavities 1230 is formed in the dielectric layer 1222. The plurality of cavities 1230 may be formed using an etching process (e.g., photo etching process) or laser process.

Stage 7 illustrates a state after interconnects 1214 are formed in and over the dielectric layer 1222, including in and over the plurality of cavities 1230. For example, a via, pad and/or traces may be formed. A plating process may be used to form the interconnects. Stage 7 illustrates that some portions of the interconnects 1214 may have a U-shape or a V-shape. The terms “U-shape” and” V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

Stage 8 illustrates a state after the carrier 1200 is decoupled (e.g., detached, removed, grinded out) from at least one dielectric layer 120 and the seed layer 1201, portions of the seed layer 1201 are removed (e.g., etched out), leaving the metallization portion 102 that includes at least one dielectric layer 120 and the plurality of metallization interconnects 122. The at least one dielectric layer 120 may represent the dielectric layer 1220 and/or the dielectric layer 1222. The plurality of metallization interconnects 122 may represent the interconnects 1202, 1212 and/or 1214. As mentioned above, the plurality of metallization interconnects 122 may include a plurality of redistribution interconnects. The plurality of metallization interconnects 122 may have a thickness in a range of about 3-7 micrometers. For example, one or more redistribution interconnects from the plurality of metallization interconnects 122 may have a thickness that is in a range of about 3-7 micrometers, which is less than the thickness of interconnects from a package substrate (e.g., 304). Similar or the same dimensions may be applicable to a plurality of metallization interconnects 142 from the metallization portion 104.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

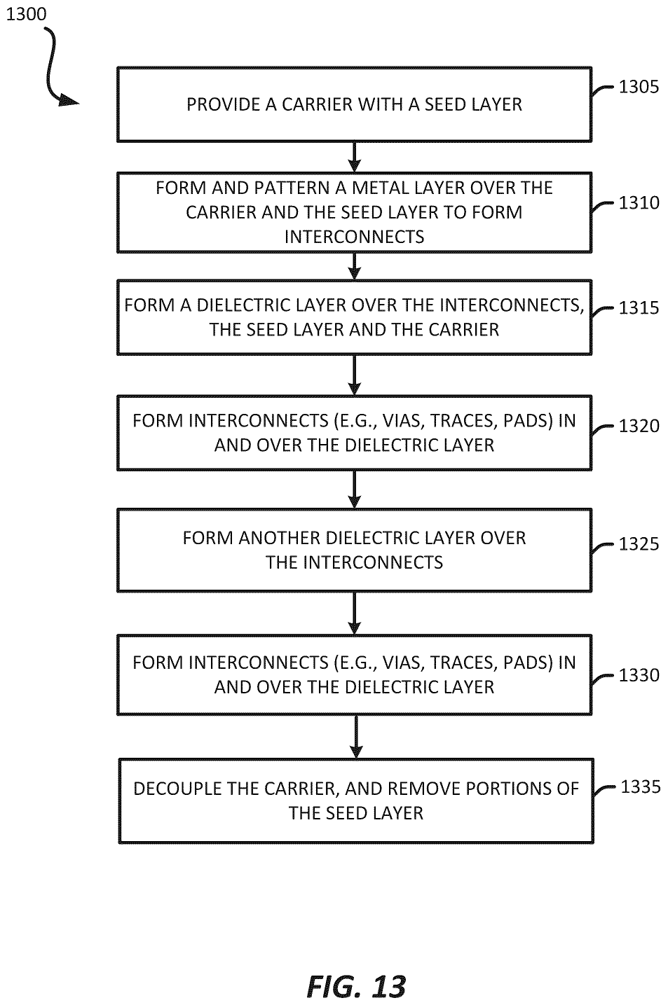

In some implementations, fabricating a metallization portion includes several processes. FIG. 13 illustrates an exemplary flow diagram of a method 1300 for providing or fabricating a metallization portion. In some implementations, the method 1300 of FIG. 13 may be used to provide or fabricate the metallization portion(s) of the disclosure. For example, the method 1300 of FIG. 13 may be used to fabricate the metallization portion 102.

It should be noted that the method 1300 of FIG. 13 may combine one or more processes in order to simplify and/or clarify the method for providing or fabricating a metallization portion. In some implementations, the order of the processes may be changed or modified.

The method provides (at 1305) a carrier (e.g., 1200). Different implementations may use different materials for the carrier 1200. The carrier 1200 may include a seed layer (e.g., 1201). The seed layer 1201 may include a metal (e.g., copper). The carrier may include a substrate, glass, quartz and/or carrier tape. Stage 1 of FIG. 12A illustrates and describes an example of a carrier with a seed layer that is provided.

The method forms and patterns (at 1310) interconnects over the carrier 1200 and the seed layer 1201. A metal layer may be patterned to form interconnects. A plating process may be used to form the metal layer and interconnects. In some implementations, the carrier and seed layer may include a metal layer. The metal layer is located over the seed layer and the metal layer may be patterned to form interconnects (e.g., 122). Stage 1 of FIG. 12A illustrates and describes an example of forming and patterning interconnects over a seed layer and a carrier.

The method forms (at 1315) a dielectric layer 1220 over the interconnects 1202, the seed layer 1201, and the carrier 1200. A deposition and/or lamination process may be used to form the dielectric layer 1220. The dielectric layer 1220 may include prepreg and/or polyimide. The dielectric layer 1220 may include a photo-imageable dielectric. Forming the dielectric layer 1220 may also include forming a plurality of cavities (e.g., 1210) in the dielectric layer 1220. The plurality of cavities may be formed using an etching process (e.g., photo etching) or laser process. Stages 2-3 of FIG. 12A illustrate and describe an example of forming a dielectric layer and cavities in the dielectric layer.

The method forms (at 1320) interconnects in and over the dielectric layer. For example, the interconnects 1212 may be formed in and over the dielectric layer 1220. A plating process may be used to form the interconnects. Forming interconnects may include providing a patterned metal layer over and/or in the dielectric layer. Forming interconnects may also include forming interconnects in cavities of the dielectric layer. Portions of the interconnects that are formed may have a U-shape or a V-shape. The terms “U-shape” and” V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). Stage 4 of FIG. 12A illustrates and describes an example of forming interconnects in and over a dielectric layer.

The method forms (at 1325) a dielectric layer 1222 over the dielectric layer 1220 and the interconnects 1212. A deposition and/or lamination process may be used to form the dielectric layer 1222. The dielectric layer 1222 may include prepreg and/or polyimide. The dielectric layer 1222 may include a photo-imageable dielectric. Forming the dielectric layer 1222 may also include forming a plurality of cavities (e.g., 1230) in the dielectric layer 1222. The plurality of cavities may be formed using an etching process (e.g., photo etching) or laser process. Stages 5-6 of FIGS. 12A-12B illustrate and describe an example of forming a dielectric layer and cavities in the dielectric layer.

The method forms (at 1330) interconnects in and over the dielectric layer. For example, the interconnects 1214 may be formed in and over the dielectric layer 1222. A plating process may be used to form the interconnects. Forming interconnects may include providing a patterned metal layer over and/or in the dielectric layer. Forming interconnects may also include forming interconnects in cavities of the dielectric layer. Portions of the interconnects that are formed may have a U-shape or a V-shape. The terms “U-shape” and” V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). Stage 7 of FIG. 12B illustrates and describes an example of forming interconnects in and over a dielectric layer, including forming post interconnects.

The method decouples (at 1335) the carrier (e.g., 1200) from the seed layer (e.g., 1201). The carrier 1200 may be detached and/or grinded off. The method may also remove (at 1335) portions of the seed layer (e.g., 1201). An etching process may be used to remove portions of the seed layer 1201. Stage 8 of FIG. 12B illustrates and describes an example of decoupling a carrier and seed layer removal.

Different implementations may use different processes for forming the metal layer(s). In some implementations, a chemical vapor deposition (CVD) process, a physical vapor deposition (PVD) process, a sputtering process, a spray coating process, and/or a plating process may be used to form the metal layer(s).

### Exemplary Electronic Devices

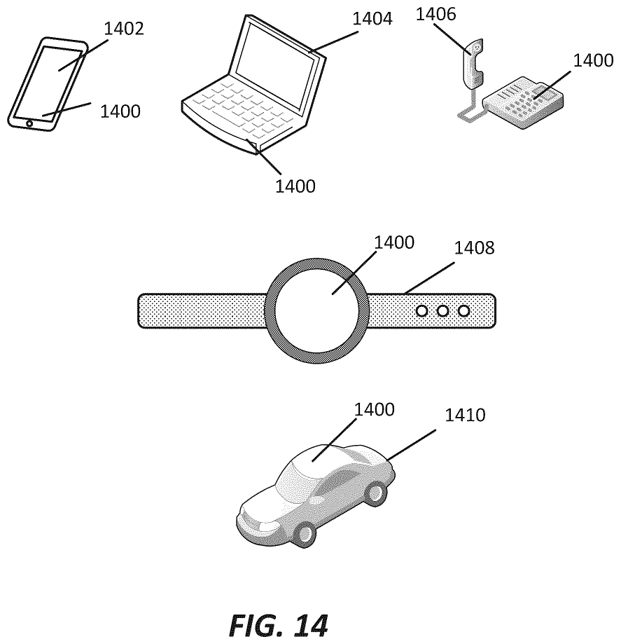

FIG. 14 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1402, a laptop computer device 1404, a fixed location terminal device 1406, a wearable device 1408, or automotive vehicle 1410 may include a device 1400 as described herein. The device 1400 may be, for example, any of the devices and/or integrated circuit (IC) packages described herein. The devices 1402, 1404, 1406 and 1408 and the vehicle 1410 illustrated in FIG. 14 are merely exemplary. Other electronic devices may also feature the device 1400 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-6, 7A-7B, 8A-8B, 9, 10A-10B, 11, 12A-12B and 13-14 may be rearranged and/or combined into a single component, process, feature or function or embodied in several components, processes, or functions. Additional elements, components, processes, and/or functions may also be added without departing from the disclosure. It should also be noted FIGS. 1-6, 7A-7B, 8A-8B, 9, 10A-10B, 11, 12A-12B and 13-14 and its corresponding description in the present disclosure is not limited to dies and/or ICs. In some implementations, FIGS. 1-6, 7A-7B, 8A-8B. 9, 10A-10B, 11, 12A-12B and 13-14 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising a first metallization portion comprising: at least one first dielectric layer; and a first plurality of metallization interconnects; a first integrated device coupled to the first metallization portion; an interconnection die coupled to the first metallization portion; a second metallization portion coupled to the first metallization portion through the interconnection die such that the first integrated device and the interconnection die are located between the first metallization portion and the second metallization portion, wherein the second metallization portion comprises: at least one second dielectric layer; and a second plurality of metallization interconnects; and an encapsulation layer coupled to the first metallization portion and the second metallization portion, wherein the encapsulation layer is located between the first metallization portion and the second metallization portion.

Aspect 2: The package of aspect 1, wherein the interconnection die comprises: a die substrate; and a plurality of die interconnects.

Aspect 3: The package of aspect 2, wherein two neighboring die interconnects from the plurality of die interconnects have a pitch in a range of about 150-270 micrometers.

Aspect 4: The package of aspects 2 through 3, wherein the plurality of die interconnects have an aspect ratio in a range of 20:1 to 10:1.

Aspect 5: The package of aspects 2 through 4, wherein the plurality of die interconnects includes a via die interconnect and a pad die interconnect.

Aspect 6: The package of aspects 2 through 5, wherein the die substrate includes glass and/or silicon.

Aspect 7: The package of aspects 1 through 6, further comprising a second integrated device coupled to the second metallization portion, wherein the first integrated device includes a first chiplet and the second integrated device includes a second chiplet.

Aspect 8: The package of aspects 1 through 7, wherein the first metallization portion includes a first redistribution portion, wherein the first plurality of metallization interconnects includes a first plurality of redistribution interconnects, wherein the second metallization portion includes a second redistribution portion, and wherein the second plurality of metallization interconnects includes a second plurality of redistribution interconnects.

Aspect 9: The package of aspect 8, wherein a first portion of a first redistribution interconnect from the first plurality of redistribution interconnects, includes a side profile that has a U-shape or a V shape, and wherein a second portion of a second redistribution interconnect from the second plurality of redistribution interconnects, includes a side profile that has a U-shape or a V shape.

Aspect 10: The package of aspects 1 through 9, wherein the interconnection die is free of transistors.

Aspect 11: A device comprising: a first package comprising: a first metallization portion comprising: at least one first dielectric layer; and a first plurality of metallization interconnects; a first integrated device coupled to the first metallization portion; means for die interconnection coupled to the first metallization portion; a second metallization portion coupled to the first metallization portion through the means for die interconnection such that the first integrated device and the means for die interconnection are located between the first metallization portion and the second metallization portion, wherein the second metallization portion comprises: at least one second dielectric layer; and a second plurality of metallization interconnects; and an encapsulation layer coupled to the first metallization portion and the second metallization portion, wherein the encapsulation layer is located between the first metallization portion and the second metallization portion.

Aspect 12: The device of aspect 11, wherein the means for die interconnection comprises: a die substrate; and a plurality of die interconnects.

Aspect 13: The device of aspect 12, wherein two neighboring die interconnects from the plurality of die interconnects have a pitch in a range of about 150-270 micrometers.

Aspect 14: The device of aspects 12 through 13, wherein the plurality of die interconnects have an aspect ratio in a range of 20:1 to 10:1.

Aspect 15: The device of aspects 12 through 14, wherein the plurality of die interconnects includes a via die interconnect and a pad die interconnect.

Aspect 16: The device of aspects 12 through 15, wherein the die substrate includes glass and/or silicon.

Aspect 17: The device of aspects 11 through 16, wherein the first metallization portion includes a first redistribution portion, wherein the first plurality of metallization interconnects includes a first plurality of redistribution interconnects, wherein the second metallization portion includes a second redistribution portion, and wherein the second plurality of metallization interconnects includes a second plurality of redistribution interconnects.

Aspect 18: The device of aspects 11 through 17, further comprising a second package coupled to the first package through a plurality of solder interconnects, wherein the second package comprises: a substrate; a second integrated device coupled to the substrate; and a second encapsulation layer coupled to the substrate and the second integrated device.

Aspect 19: The device of aspects 11 through 18, wherein the means for die interconnection is free of transistors.

Aspect 20: The device of aspects 11 through 19, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating a package, comprising: providing a first metallization portion; coupling a first integrated device to the first metallization portion; coupling an interconnection die to the first metallization portion; forming an encapsulation layer over the first metallization portion, the first integrated device and the interconnection die; and forming a second metallization portion over the encapsulation layer such that the second metallization portion is coupled to the first metallization portion through the interconnection die.

Aspect 22: The method of aspect 21, further comprising coupling a second integrated device to the second metallization portion.

Aspect 23: The method of aspect 21, further comprising coupling a second package to the second metallization portion through a plurality of solder interconnects, wherein the second package comprises: a substrate; a second integrated device coupled to the substrate; and a second encapsulation layer coupled to the substrate and the second integrated device.

Aspect 24: The method of aspects 21 through 23, wherein the interconnection die comprises: a die substrate; and a plurality of die interconnects.

Aspect 25: The method of aspect 24, wherein two neighboring die interconnects from the plurality of die interconnects have a pitch in a range of about 150-270 micrometers.

Aspect 26: The method of aspects 24 through 25, wherein the plurality of die interconnects have an aspect ratio in a range of 20:1 to 10:1.

Aspect 27: The method of aspects 21 through 26, wherein the first metallization portion includes a first redistribution portion comprising a first plurality of redistribution interconnects, and wherein forming the second metallization portion includes forming a second redistribution portion comprising a second plurality of redistribution interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first metallization portion comprising:
at least one first dielectric layer; and
a first plurality of metallization interconnects;
a first integrated device coupled to the first metallization portion;
an interconnection die coupled to the first metallization portion;
a second metallization portion coupled to the first metallization portion through the interconnection die such that the first integrated device and the interconnection die are located between the first metallization portion and the second metallization portion, wherein the second metallization portion comprises:
at least one second dielectric layer; and
a second plurality of metallization interconnects; and
an encapsulation layer coupled to the first metallization portion and the second metallization portion, wherein the encapsulation layer is located between the first metallization portion and the second metallization portion.

2. The package of claim 1, wherein the interconnection die comprises:
a die substrate; and
a plurality of die interconnects.

3. The package of claim 2, wherein two neighboring die interconnects from the plurality of die interconnects have a pitch in a range of about 150-270 micrometers.

4. The package of claim 2, wherein the plurality of die interconnects have an aspect ratio in a range of 20:1 to 10:1.

5. The package of claim 2, wherein the plurality of die interconnects includes a via die interconnect and a pad die interconnect.

6. The package of claim 2, wherein the die substrate includes glass and/or silicon.

7. The package of claim 1, further comprising a second integrated device coupled to the second metallization portion, wherein the first integrated device includes a first chiplet and the second integrated device includes a second chiplet.

8. The package of claim 1,
wherein the first metallization portion includes a first redistribution portion,
wherein the first plurality of metallization interconnects includes a first plurality of redistribution interconnects,
wherein the second metallization portion includes a second redistribution portion, and
wherein the second plurality of metallization interconnects includes a second plurality of redistribution interconnects.

9. The package of claim 8,
wherein a first portion of a first redistribution interconnect from the first plurality of redistribution interconnects, includes a side profile that has a U-shape or a V shape, and
wherein a second portion of a second redistribution interconnect from the second plurality of redistribution interconnects, includes a side profile that has a U-shape or a V shape.

10. The package of claim 1, wherein the interconnection die is free of transistors.

11. A device comprising:
a first package comprising:
a first metallization portion comprising:
at least one first dielectric layer; and
a first plurality of metallization interconnects;
a first integrated device coupled to the first metallization portion;
means for die interconnection coupled to the first metallization portion;
a second metallization portion coupled to the first metallization portion through the means for die interconnection such that the first integrated device and the means for die interconnection are located between the first metallization portion and the second metallization portion, wherein the second metallization portion comprises:
at least one second dielectric layer; and
a second plurality of metallization interconnects; and
an encapsulation layer coupled to the first metallization portion and the second metallization portion, wherein the encapsulation layer is located between the first metallization portion and the second metallization portion.

12. The device of claim 11, wherein the means for die interconnection comprises:
a die substrate; and
a plurality of die interconnects.

13. The device of claim 12, wherein two neighboring die interconnects from the plurality of die interconnects have a pitch in a range of about 150-270 micrometers.

14. The device of claim 12, wherein the plurality of die interconnects have an aspect ratio in a range of 20:1 to 10:1.

15. The device of claim 12, wherein the plurality of die interconnects includes a via die interconnect and a pad die interconnect.

16. The device of claim 12, wherein the die substrate includes glass and/or silicon.

17. The device of claim 11,
wherein the first metallization portion includes a first redistribution portion,
wherein the first plurality of metallization interconnects includes a first plurality of redistribution interconnects,
wherein the second metallization portion includes a second redistribution portion, and
wherein the second plurality of metallization interconnects includes a second plurality of redistribution interconnects.

18. The device of claim 11, further comprising a second package coupled to the first package through a plurality of solder interconnects, wherein the second package comprises:
a substrate;
a second integrated device coupled to the substrate; and
a second encapsulation layer coupled to the substrate and the second integrated device.

19. The device of claim 11, wherein the means for die interconnection is free of transistors.

20. The device of claim 11, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating a package, comprising:
providing a first metallization portion;
coupling a first integrated device to the first metallization portion;
coupling an interconnection die to the first metallization portion;
forming an encapsulation layer over the first metallization portion, the first integrated device and the interconnection die; and
forming a second metallization portion over the encapsulation layer such that the second metallization portion is coupled to the first metallization portion through the interconnection die.

22. The method of claim 21, further comprising coupling a second integrated device to the second metallization portion.

23. The method of claim 21, further comprising coupling a second package to the second metallization portion through a plurality of solder interconnects, wherein the second package comprises:
a substrate;
a second integrated device coupled to the substrate; and
a second encapsulation layer coupled to the substrate and the second integrated device.

24. The method of claim 21, wherein the interconnection die comprises:
a die substrate; and
a plurality of die interconnects.

25. The method of claim 24, wherein two neighboring die interconnects from the plurality of die interconnects have a pitch in a range of about 150-270 micrometers.

26. The method of claim 24, wherein the plurality of die interconnects have an aspect ratio in a range of 20:1 to 10:1.

27. The method of claim 21,
wherein the first metallization portion includes a first redistribution portion comprising a first plurality of redistribution interconnects, and
wherein forming the second metallization portion includes forming a second redistribution portion comprising a second plurality of redistribution interconnects.
